(19) United States
(12) Patent Application Publication
(10) Pub. No.: US 2012/0325537 A1
(43) Pub. Date: Dec. 27, 2012

(54) CIRCUIT BOARD, ELECTRONIC APPARATUS, AND NOISE BLOCKING METHOD

(75) Inventors: Hiroshi Toyao, Tokyo (JP); Manabu Kusumoto, Tokyo (JP); Naoki Kobayashi, Tokyo (JP); Noriaki Ando, Tokyo (JP)

(73) Assignee: NEC CORPORATION, Tokyo (JP)

(21) Appl. No.: 13/583,461

(22) PCT Filed: Feb. 18, 2011
(86) PCT No.: PCT/JP2011/000911

§ 371 Date: Sep. 7, 2012

(30) Foreign Application Priority Data
Mar. 8, 2010 (JP) 2010-051079

(51) Int. Cl. H05K 1/16

(52) U.S. Cl. 174/260

(57) ABSTRACT

A circuit board (100) includes power supply planes (141, 143) arranged with gaps (147) in a D layer (140), connection members (182, 183, 184) electrically connecting at least one of the power supply planes (141, 143) to an electronic device (181), plural conductor elements (121) repeatedly arranged to surround at least some of the gaps (147) and the connection members (182, 183, 184), and ground planes (111, 171) being located in an A layer (110) or a G layer (170) and extending in a second region or a third region including a region opposing the first region and a region opposing the conductor elements (121).

### TECHNICAL FIELD

The present invention relates to a circuit board, an electronic apparatus, and a noise blocking method.

### BACKGROUND ART

In electronic apparatuses, noise generated from an electronic device propagates in a parallel plate including a power supply plane and a ground plane as a kind of waveguide and may adversely affect other electronic devices or nearby radio circuits. Accordingly, in such an electronic apparatus, noise countermeasures are generally taken and various techniques have been developed.

In recent years, it has been known that propagation characteristics of electromagnetic waves can be controlled by periodically arranging a conductor pattern having a specific structure (hereinafter, referred to as a metamaterial). Particularly, a metamaterial constructed to suppress propagation of electromagnetic waves in a specific frequency band is referred to as an electromagnetic bandgap structure (hereinafter, referred to as an EBG structure). A noise countermeasure using the EBG structure has attracted attention.

An example of such a technique is described in Patent Document 1 (U.S. Pat. No. 6,262,495). FIG. 2 of Patent Document 1 shows a structure, that is, a mushroom-like EBG structure, in which plural island-like conductor elements are arranged over a sheet-like conductive plane and the respective island-like conductor elements are connected to the conductive plane through vias.

Another example of such a technique is described in Patent Document 2 (JP-A-2006-253929). FIG. 4 of Patent Document 2 shows an EBG structure constructed by connecting two opposing conductors to each other. By giving a conductor pattern, which can provide a large reflection coefficient at a Bragg frequency, to the lower conductor among the two opposing conductors, the inductance component is increased.

### RELATED DOCUMENT

### Patent Document

[Patent Document 1] U.S. Pat. No. 6,262,495

[Patent Document 2] JP-A-2006-253929

### DISCLOSURE OF THE INVENTION

In an electronic apparatus including a multi-layered board, when plural conductors are formed with a gap therebetween in a conductive layer and an electronic device is connected to the conductors, noise propagating in the conductors is radiated from the gaps and the noise leaks to a layer other than the conductive layer or to the outside of the multi-layered board. Accordingly, even when an EBG structure is constituted in the conductive layer, a satisfactory noise countermeasure is not achieved.

The invention is made in consideration of the above-mentioned circumstances and an object thereof is to provide a circuit board, an electronic apparatus, and a noise blocking method, which include plural separated conductors and can prevent leakage of noise radiated from the gaps between the conductors.

According to an aspect of the invention, there is provided a circuit board including: a plurality of first conductors that are arranged with gaps in a first layer; a first connection member that electrically connects at least one of the plurality of first conductors to an electronic device; a plurality of second conductors that are repeatedly arranged to surround a first region including at least some of the gaps and at least some of connection points between the first connection member and the first conductors and that are opposing the first conductors; a third conductor that is located in a second layer and that extends in a second region including the first region and a region opposing the second conductors; and a fourth conductor that is located in a third layer opposing the second layer with the first layer interposed therebetween and that extends in a third region including the first region and a region opposing the second conductor.

According to another aspect of the invention, there is provided an electronic apparatus including: a plurality of first conductors that are arranged with gaps in a first layer; an electronic device that is electrically connected to at least one of the plurality of first conductors; a plurality of second conductors that are repeatedly arranged to surround a first region including at least some of the gaps and at least some of connection points to the electronic device over the first conductors and that are opposing the first conductors; a third conductor that is located in a second layer and that extends in a second region including the first region and a region opposing the second conductors; and a fourth conductor that is located in a third layer opposing the second layer with the first layer interposed therebetween and that extends in a third region including the first region and a region opposing the second conductor.

According to still another aspect of the invention, there is provided a noise blocking method including: when noise generated from an electronic device propagates in at least one of a space between any of a plurality of first conductors arranged with gaps in a first layer and a third conductor extending in a second layer and a space between any of the plurality of first conductors and a fourth conductor extending in a third layer opposing the second layer with the first layer interposed therebetween and is radiated from the gaps to the outside, blocking the radiated noise by the use of the third conductor and the fourth conductor; and blocking the noise in a space in which any of a plurality of second conductors repeatedly arranged to surround a first region including at least some of the gaps and at least some of connection points to the electronic device of the first conductors and opposing the first conductors is opposing the third conductor or the fourth conductor.

According to the aspects of the invention, it is possible to provide a circuit board, an electronic apparatus, and a noise blocking method, which include plural separated conductors and can prevent leakage of noise radiated from the gaps between the conductors.

### BRIEF DESCRIPTION OF THE DRAWINGS

FIG. 1 shows a plan view and a cross-sectional view of a circuit board according to a first embodiment of the invention.

FIG. 2 is a diagram illustrating a D layer of the circuit board according to the first embodiment.

FIG. 3 is a diagram illustrating a B layer and an F layer of the circuit board according to the first embodiment.

FIG. 4 is a diagram illustrating an A layer and a G layer of the circuit board according to the first embodiment.

FIG. 5 is a diagram illustrating a C layer and an E layer of the circuit board according to the first embodiment.

FIG. 6 is a diagram illustrating examples of the shape and the position of conductor elements or connection members used in the first embodiment.

FIG. 7 is a diagram illustrating examples of the shape and the position of conductor elements or connection members used in the first embodiment.

FIG. 8 is a diagram illustrating examples of the shape and the position of conductor elements or connection members used in the first embodiment.

FIG. 9 is a diagram illustrating examples of the shape and the position of conductor elements or connection members used in the first embodiment.

FIG. 10 is a diagram illustrating examples of the shape and the position of conductor elements or connection members used in the first embodiment.

FIG. 11 is a diagram illustrating examples of the shape and the position of conductor elements or connection members used in the first embodiment.

FIG. 12 is a diagram illustrating examples of the shape and the position of conductor elements or connection members used in the first embodiment.

FIG. 13 is a diagram illustrating examples of the shape and the position of conductor elements or connection members used in the first embodiment.

FIG. 14 shows a plan view and a cross-sectional view of a circuit board according to a second embodiment of the invention.

FIG. 15 is a diagram illustrating a C layer and an E layer of the circuit board according to the second embodiment.

FIG. 16 is a diagram illustrating a B layer, a D layer, and an F layer of the circuit board according to the second embodiment.

FIG. 17 is a diagram illustrating an A layer and a G layer of the circuit board according to the second embodiment.

FIG. 18 is a diagram illustrating examples of the shape and the position of conductor elements or connection members used in the second embodiment.

FIG. 19 is a diagram illustrating examples of the shape and the position of conductor elements or connection members used in the second embodiment.

FIG. 20 is a diagram illustrating examples of the shape and the position of conductor elements or connection members used in the second embodiment.

FIG. 21 is a diagram illustrating examples of the shape and the position of conductor elements or connection members used in the second embodiment.

FIG. 22 shows a plan view and a cross-sectional view of a circuit board according to a third embodiment of the invention.

FIG. 23 is a diagram illustrating an example of the shape of a conductor element used in the third embodiment.

FIG. 24 is a diagram illustrating an example of the shape of a conductor element used in the third embodiment.

FIG. 25 is a diagram illustrating an example of the shape of a conductor element used in the third embodiment.

FIG. 26 is a diagram illustrating an example of the shape of a conductor element used in the third embodiment.

FIG. 27 is a diagram illustrating an example of the shape of a conductor element used in the third embodiment.

FIG. 28 shows a plan view and a cross-sectional view of a circuit board according to a fourth embodiment of the invention.

### DESCRIPTION OF EMBODIMENTS

Hereinafter, embodiments of the invention will be described with reference to the accompanying drawings. In all the drawings, like elements are referenced by like reference numerals and will not be repeatedly described.

### First Embodiment

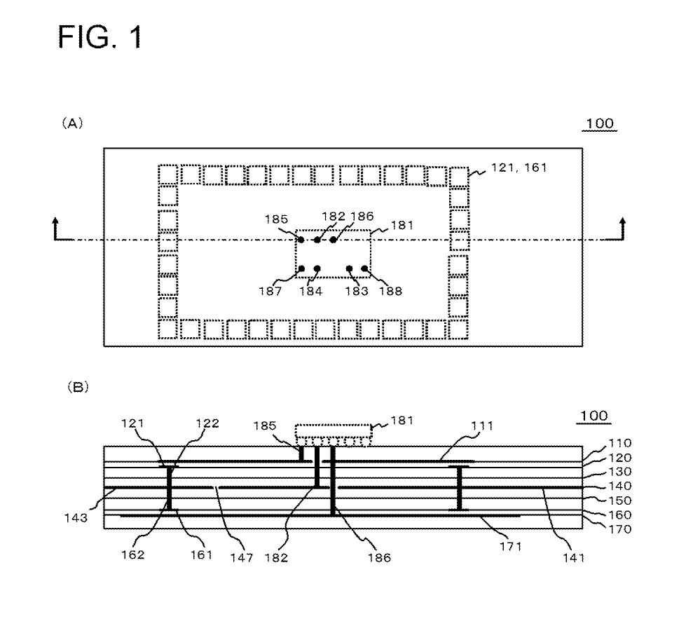

FIG. 1 shows a plan view and a cross-sectional view of a circuit board 100 according to a first embodiment of the invention. More specifically, FIG. 1(A) is a plan view of the circuit board 100 and FIG. 1(B) is a cross-sectional view of the circuit board 100 taken along the indicated sectional line in FIG. 1(A). The circuit board 100 is a multi-layered board including at least an A layer 110, a B layer 120, a C layer 130, a D layer 140, an E layer 150, an F layer 160, and a G layer 170 which are opposing each other. The circuit board 100 may include a layer other than the seven layers. For example, a dielectric layer may be located between the layers. The circuit board 100 may further include holes or vias not shown in the drawing without conflicting with the configuration of the invention. Signal lines may be arranged in the seven layers without conflicting with the configuration of the invention.

In FIG. 1, an electronic device 181 is indicated by a dotted line. This means that the electronic device 181 is not yet mounted. That is, a prearranged region on which the electronic device 181 should be mounted is determined on the surface of the circuit board 100, and the circuit board includes a connection member 182 connecting the electronic device 181 to a power supply plane 141, a connection member 183 connecting the electronic device 181 to a power supply plane 142, and a connection member 184 connecting the electronic device 181 to a power supply plane 143. The circuit board 100 includes a connection member 185 connecting the electronic device 181 to a ground plane 111 and a connection member 186 connecting the electronic device 181 to a ground plane 171. The circuit board 100 includes a connection member 187 connecting the electronic device 181 to a signal line 131 and a connection member 188 connecting the electronic device 181 to a signal line 188. Here, the electronic device 181 is assumed as a device such as an LSI. The number of electronic devices 181 mounted on the circuit board 100 may be one or two or more.

In FIG. 1(A), since conductor elements 121 and 161 are located under the uppermost layer, they are indicated by dotted lines. Since the positions of both the conductor elements overlap in a plan view, a single square represents both the conductor element 121 and the conductor element 161. The conductor element 121 and the conductor element 161 may not necessarily be arranged at positions overlapping in a plane view but may be arranged at positions not overlapping in a plan view. The shape of the conductor element 121 or the conductor element 161 is not limited to a square, but may be triangular or hexagonal.

In the circuit board 100 according to this embodiment, the prearranged region on which the electronic device 181 should be mounted is located in a region overlapping with some of the gaps 147. This is because the connection to the power supply planes 141, 142, and 143 is relatively facilitated when it is assumed that power is supplied to the single electronic device 181 from the respective power supply planes 141, 142, and 143. However, the electronic device 181 is not necessarily in the region overlapping with the gaps 147 in a plan view.

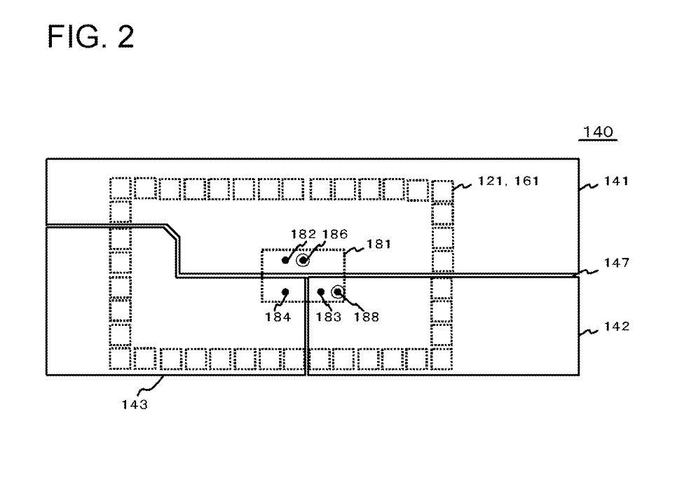

FIG. 2 is a diagram illustrating the D layer 140 of the circuit board 100. In the D layer 140 (the first layer), the power supply planes 141, 142, and 143 (the plural first conductors) are arranged with the gaps 147. Since the gaps 147 are filled with an insulator, the power supply planes 141, 142, and 143 are insulated from each other and thus can apply different potentials to the power supply planes, respectively. However, different potentials may not be necessarily supplied to the power supply planes, but the same potential may be applied thereto.

The power supply plane 141 includes a connection point connected to the connection member 182, the power supply plane 142 includes a connection point connected to the connection member 183, and the power supply plane 143 includes a connection point connected to the connection member 184. In this embodiment, the connection points connected to the connection members 182, 183, and 184 are disposed in all the power supply planes 141, 142, and 143 shown in the drawing, but may not necessarily be disposed in all the power supply planes. That is, the connection points connected to the connection members 182, 183, and 184 have only to be disposed in at least one of the power supply planes 141, 142, and 143. Since the connection member 186 is connected to the ground plane 171, the connection member passes through an opening formed in the power supply plane 141 and is insulated from the power supply plane 141.

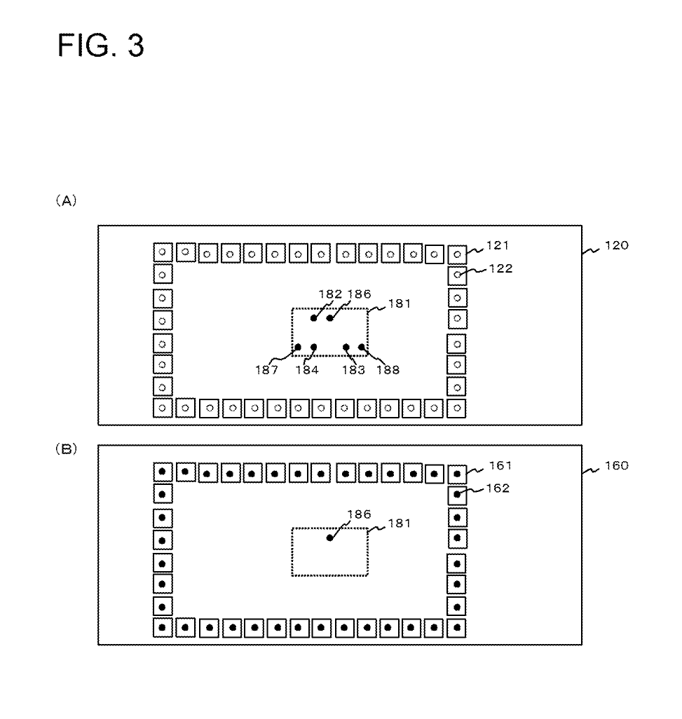

FIG. 3 is a diagram illustrating the B layer 120 and the F layer 160 of the circuit board 100. In the B layer 120 which is an interlayer between the D layer 140 and the A layer 110, plural conductor elements 121 (the second conductors) are repeatedly arranged to surround a first region including at least some of the gaps 147 and the connection points between the connection members 182, 183, and 184 and the power supply planes 141, 142, and 143 and are opposing the power supply plane 141 (or 142 or 143). In the F layer 160 which is an interlayer between the D layer 140 and the G layer 170, plural conductor elements 161 (the second conductors) are repeatedly arranged to surround the first region and are opposing the power supply plane 141 (or 142 or 143). More specifically, the first region includes the connection points existing in the different power supply planes 141, 142, and 143. Here, the conductor elements 121 and 131 are island-like conductors arranged with a gap interposed therebetween. A region in which the conductor elements 121 are not arranged in the B layer 120 or a region in which the conductor elements 161 are not arranged in the F layer 160 is formed in an insulator and is insulated from the connection members 182, 183, 184, and 186.

Here, the above-mentioned expression “repeatedly arranged” means that three or more conductor elements 121 and 161 are continuously arranged with a gap interposed therebetween. It is stated above that the conductor elements 121 and 161 are arranged to surround the first region, but the conductor elements 121 and 161 are separated with a gap and thus do not surround the overall planar direction of the first region. The gaps between the conductor element 121 and the gaps between the conductor elements 161 can be determined to such an extent to satisfactorily suppress noise of a frequency band to be suppressed.

The conductor elements 121 and 161 may not be arranged in such a way when it is not necessary to suppress the propagation of noise in some directions of the first region.

The conductor elements 121 are connected to any one of the power supply planes 141, 142, and 143 through the connection member 122 and the conductor elements 161 are connected to any one of the power supply planes 141, 142, and 143 through the connection member 162. It is shown in FIG. 1 that the connection member 122 and the connection member 162 match each other in a plan view, but both do not necessarily match each other. Here, it is stated that the connection members 122 and 162 are connected to any one of the power supply planes 141, 142, and 143, but the connection members 122 and 162 may be connected to one or both of the ground planes 111 and 171. This configuration will be described later.

The conductor elements 121 and 161 do not have to be connected to the power supply planes 141, 142, and 143, but may be connected to the ground planes 111 and 171 or may not connected to any thereof. Here, the conductor elements 121 and 161 connected to the power supply planes 141, 142, and 143 should not be connected to the ground planes 111 and 171.

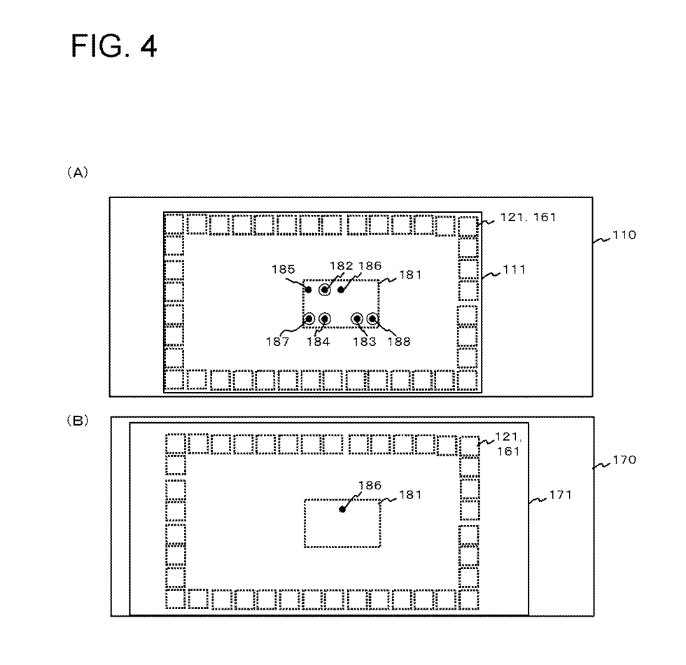

FIG. 4 is a diagram illustrating the A layer 110 and the G layer 170 of the circuit board 100. The ground plane 111 (the third conductor) is a sheet-like conductor, is located in the A layer 110 (the second layer) which is a layer above the D layer 140, and extends in a second region including a region opposing the first region and a region opposing the conductor elements 121. The ground plane 171 (the fourth conductor) is a sheet-like conductor, is located in the G layer 170 (the third layer) which is a layer below the D layer 140, and extends in a third region including a region opposing the first region and a region opposing the conductor elements 161. Here, it is shown that the second region in which the ground plane 111 extends and the third region in which the ground plane 171 extends do not match each other when seen in a plan view, but both region may match each other.

The ground plane 111 or the ground plane 171 is supplied with a reference potential by grounding or the like. Since the connection members 182, 183, and 184 are connected to the power supply planes 141, 142, and 143, the connection members pass through openings formed in the ground plane 111 and are insulated from the ground plane 111. A region in which the ground plane 111 is not formed in the A layer 110 or a region in which the ground plane 171 is not formed in the G layer 170 maybe formed of an insulator, or maybe formed of a conductor, or may be formed of a mixture thereof.

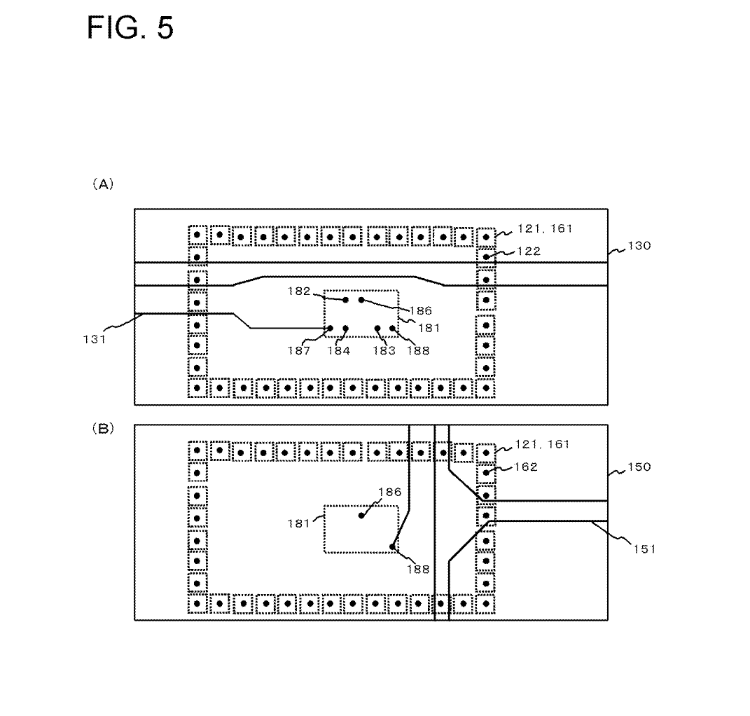

FIG. 5 is a diagram illustrating the C layer 130 and the E layer 150 of the circuit board 100. The C layer 130 and the E layer 150 are so-called wiring layers and a signal line 131 and a signal line 151 are arranged therein. The arrangement patterns of the signal line 131 and the signal line 151 are not limited to the shown patterns, but they may be arranged so as not to be electrically connected to the connection members 122, 162, 182, 183, 184, 185, and 186. For example, the signal lines 131 and 151 connected to a signal line of another layer may be arranged or the signal lines 131 and 151 connected to the electronic device 181 may be arranged. In this embodiment, the C layer 130 in which the signal line 131 is arranged is located between the B layer 120 and the D layer 140, but is not limited to this configuration and may be located among the A layer 110 to the G layer 170. In this embodiment, the E layer 150 in which the signal line 151 is arranged is located between the D layer 140 and the F layer 160, but is not limited to this configuration and may be located between the A layer 110 to the G layer 170.

In the circuit board 100, two noise propagation paths of a first parallel plate including the ground plane 111 and the power supply plane 141 (or 142 or 143) and a second parallel plane including the ground plane 171 and the power supply plane 141 (or 142 or 143) can be considered. By employing this configuration, the conductor element 121 constitutes a unit cell of an EBG structure along with the opposing power supply planes 141, 142, and 143, the opposing ground plane 111, and the connection member 122. By using an EBG structure in which the unit cell is repeatedly arranged, it is possible to suppress noise propagating in the first parallel plate. The conductor element 161 constitutes a unit cell of an EBG structure along with the opposing power supply planes 141, 142, and 143, the opposing ground plane 171, and the connection member 162. By using an EBG structure in which the unit cell is repeatedly arranged, it is possible to suppress noise propagating in the second parallel plate. It is preferable that each EBG structure includes the frequency of noise generated from the electronic device 181 in the bandgap range thereof. The unit cell of the EBG structure constructed in the circuit board 100 according to this embodiment is a structure including the connection member 122 or the connection member 162, but is not limited to this configuration. That is, the circuit board 100 may not necessarily have the connection member in an interlayer between the ground plane 111 and the power supply plane 141 (or 142 or 143) or an interlayer between the ground plane 171 and the power supply plane 141 (or 142 or 143). Unit cells of various EBG structures applicable to the circuit board 100 will be described later.

Here, the unit cell is a minimum unit constituting an EBG structure. Since the circuit board 100 includes the unit cells which are repeatedly arranged, it is possible to effectively suppress noise propagating from the first region to the outside and to confine the noise in the first region.

By adjusting the gap between the conductor element 121 and the power supply planes 141, 142, and 143, the gap between the conductor element 121 and the ground plane 111, the thickness of the connection members 122 and 162, the mutual gap of the conductor elements 121, the mutual gap of the conductor elements 161, and the like, it is possible to set the frequency band to be suppressed to a desired value.

The unit cells which are repeatedly arranged, particularly, the mutual gaps of the conductor elements 121 and 161 or the connection members 122 and 162, are preferably periodic. This is because when the unit cells are periodically arranged, electromagnetic waves propagating in the EBG structure cause Bragg reflection due to the periodicity, thereby achieving the effect of suppressing noise propagation in a broader band. Here, the mutual gap of the conductor elements 121 and the mutual gap of the conductor elements 161 may not necessarily match each other. Similarly, the mutual gap of the connection members 122 and the mutual gap of the connection members 162 may not necessarily match each other. The unit cells may not necessarily be arranged periodically, but by repeatedly arranging the unit cells so as to surround the first region, it is possible to achieve the effects of the invention.

The shapes or the positions of the conductor elements 121 and 161 or the connection members 122 and 162 shown in FIGS. 1 to 5 are only examples, and various examples can be employed as long as they can constitute an EBG structure.

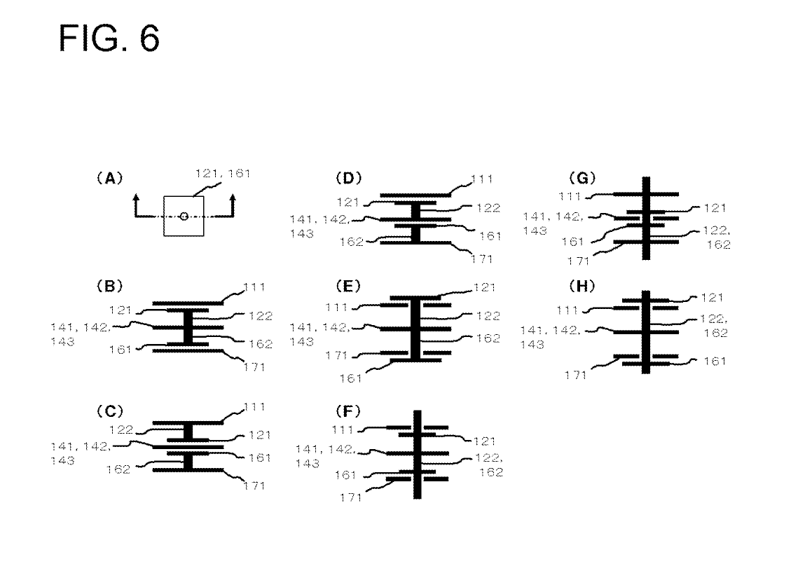

FIGS. 6 to 13 are diagrams illustrating the shapes or the positions of the conductor elements 121 and 161 or the connection members 122 and 162. FIGS. 6 to 13 focus on the single conductor element 121 or the single conductor element 161 and shows an enlarged view of the periphery thereof. The structures shown in FIGS. 6 to 13 constitute a single unit cell or plural unit cells, and the circuit board 100 includes one of the unit cells or a combination thereof.

FIG. 6 (A) is a plan view illustrating an example of the conductor elements 121 and 161. The conductor elements 121 and 161 shown in the drawing are rectangular and are connected to the connection members 122 and 162.

FIGS. 6(B) to 6(H) are cross-sectional views of the circuit board 100 around the conductor elements 121 and 161 shown in FIG. 6(A). Among these, FIGS. 6(B) to 6(E) show an example where the connection member 122 and the connection member 162 are formed of different members. In FIG. 6(B), the connection members 122 and 162 are connected to the power supply planes 141, 142, and 143, which are equivalent to the configuration described with reference to FIGS. 1 to 5. In FIG. 6(C), the connection member 122 is connected to the ground plane 111 and the connection member 162 is connected to the ground plane 171. In FIG. 6(D), the connection member 122 is connected to the power supply planes 141, 142, and 143, and the connection member 162 is connected to the ground plane 171. In FIG. 6(E), the B layer 120 in which the conductor element 121 is formed is opposing the D layer 140 (the first layer) with the A layer 110 (the second layer) interposed therebetween. The F layer 160 in which the conductor element 161 is formed is opposing the D layer 140 (the first layer) with the G layer 170 (the third layer) interposed therebetween. The connection members 122 and 162 are connected to the power supply planes 141, 142, and 143, and pass through the openings formed in the ground planes 111 and 171. The conductor elements 121 and 161 are opposing the ground planes 111 and 171 and are electrically connected to the connection members 122 and 162 passing through the openings. The openings formed in the ground planes 111 and 117 are arranged to cause the connection members 122 and 162 to pass therethrough and the conductor elements 121 and 161 are arranged to oppose the openings. Accordingly, it is possible to substantially prevent the leakage of noise from the openings.

The structures shown in FIGS. 6(B) to 6(E) are so-called mushroom-like EBG structures. Specifically, the connection members 122 and 162 correspond to the stem part of a mushroom and form inductance. On the other hand, in FIGS. 6(B) and 6(E), the conductor elements 121 and 161 correspond to the head part of a mushroom and form capacitance along with the opposing ground planes 111 and 171. In FIG. 6(C), the conductor elements 121 and 161 correspond to the head part of a mushroom and form capacitance along with the opposing power supply plane 141 (or 142 or 143). In FIG. 6(D), the conductor elements 121 and 161 correspond to the head part of a mushroom and form capacitance along with the opposing ground plane 111 and the opposing power supply plane 141 (or 142 or 143).

The mushroom-like EBG structure can be expressed by an equivalent circuit in which a parallel plate is shunted with a serial resonance circuit including the capacitance and the inductance and the resonance frequency of the serial resonance circuit gives the central frequency of a bandgap. Accordingly, it is possible to achieve a fall in the frequency of the bandgap range by causing the conductor elements 121 and 161 to approach the opposing planes forming the capacitance to increase the capacitance. However, even when the conductor elements 121 and 161 are not made to approach the opposing planes, the substantial effect of the invention is not affected at all.

FIGS. 6(F) to 6(H) show examples where the connection member 122 and the connection member 162 are the same penetration via. In FIG. 6(F), the penetration via is connected to the power supply planes 141, 142, and 143 and passes through the openings of the ground planes 111 and 171. In FIG. 6(G), the penetration via is connected to the ground plane 111 and 171 and passes through the openings of the power supply planes 141, 142, and 143. In FIG. 6(H), the B layer 120 in which the conductor element 121 is formed is opposing the D layer 140 (the first layer) with the A layer 110 (the second layer) interposed therebetween. The F layer 160 in which the conductor element 161 is formed is opposing the D layer 140 (the first layer) with the G layer 170 (the third layer) interposed therebetween. The penetration vias (the connection members 122 and 162) are connected to the power supply planes 141, 142, and 143 and pass through the openings formed in the ground planes 111 and 171. The conductor elements 121 and 161 are opposing the ground planes 111 and 171 and are electrically connected to the penetration vias passing through the corresponding openings.

The structures shown in FIGS. 6(F) to 6(H) are modified examples of a mushroom-like EBG structure. Specifically, the connection members 122 and 162 correspond to the stem part of a mushroom and form inductance. On the other hand, in FIGS. 6(F) and 6(H), the conductor elements 121 and 161 correspond to the head part of a mushroom and form capacitance along with the opposing ground planes 111 and 171. In FIG. 6(G), the conductor elements 121 and 161 correspond to the head part of a mushroom and form capacitance along with the opposing power supply plane 141 (or 142 or 143).

Similarly to the mushroom-like EBG structure, the structures shown in FIGS. 6(F) to 6(H) can be expressed by an equivalent circuit in which a parallel plate is shunted with a serial resonance circuit including the capacitance and the inductance and the resonance frequency of the serial resonance circuit gives the central frequency of a bandgap. Accordingly, it is possible to achieve a fall in the frequency of the bandgap range by causing the conductor elements 121 and 161 to approach the opposing planes forming the capacitance to increase the capacitance. However, even when the conductor elements 121 and 161 are not made to approach the opposing planes, the substantial effect of the invention is not affected at all.

By employing the configurations shown in FIGS. 6(F) to 6(H), it is possible to form an EBG structure in the first and second parallel plates using the penetration via. In general, a non-penetration via is formed by first processing a via for each layer and then stacking the layers, but a penetration via is formed by stacking all the layers, forming a through-hole with a drill, and then plating the inner surface of the through-hole. Accordingly, it is possible to reduce the manufacturing cost, compared with a case where a non-penetration via is used.

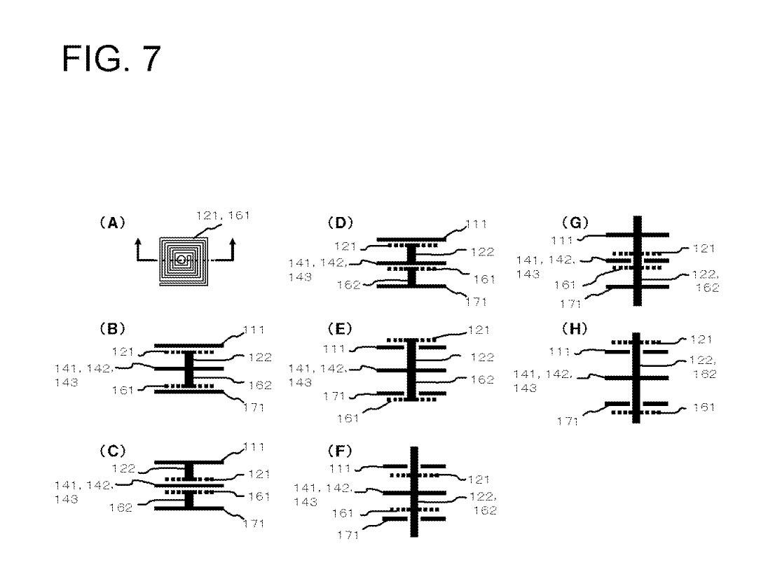

FIG. 7(A) is a plan view illustrating an example of the conductor elements 121 and 161. The conductor elements 121 and 161 shown in the drawing are spiral transmission lines formed in a planar direction, where one end thereof is connected to the connection members 122 and 161 and the other end thereof is an open end.

FIGS. 7(B) to 7(H) are cross-sectional views of the circuit board 100 around the conductor elements 121 and 161 shown in FIG. 7(A). Among these, FIGS. 7(B) to 7(E) show an example where the connection member 122 and the connection member 162 are formed of different members. In FIG. 7(B), the connection members 122 and 162 are connected to the power supply planes 141, 142, and 143. In FIG. 7(C), the connection member 122 is connected to the ground plane 111 and the connection member 162 is connected to the ground plane 171. In FIG. 7(D), the connection member 122 is connected to the power supply planes 141, 142, and 143, and the connection member 162 is connected to the ground plane 171. In FIG. 7(E), the B layer 120 in which the conductor element 121 is formed is opposing the D layer 140 (the first layer) with the A layer 110 (the second layer) interposed therebetween. The F layer 160 in which the conductor element 161 is formed is opposing the D layer 140 (the first layer) with the G layer 170 (the third layer) interposed therebetween. The connection members 122 and 162 are connected to the power supply planes 141, 142, and 143, and pass through the openings formed in the ground planes 111 and 171. The conductor elements 121 and 161 are opposing the ground planes 111 and 171 and are electrically connected to the connection members 122 and 162 passing through the openings.

The structures shown in FIGS. 7(B) to 7(E) constitute an open stub type EBG structure in which a microstrip line including the conductor elements 121 and 161 serves as an open stub. Specifically, the connection members 122 and 162 form inductance. On the other hand, in FIGS. 7(B) and 7(E), the conductor elements 121 and 161 are electrically coupled to the opposing ground planes 111 and 171 to form a microstrip line having the ground planes 111 and 171 as a return path. In FIG. 7(C), the conductor elements 121 and 161 are electrically coupled to the opposing power supply plane 141 (or 142 or 143) to form a microstrip line having the power supply plane 141 (or 142 or 143) as a return path. In FIG. 7(D), the conductor elements 121 and 161 are electrically coupled to the opposing ground plane 111 and the opposing power supply plane 141 (or 142 or 143) to form a microstrip line having the ground plane 111 and the power supply plane 141 (or 142 or 143) as a return path. One end of the microstrip line is an open end and is configured to serve as an open stub.

The open stub type EBG structure can be expressed by an equivalent circuit in which a parallel plate is shunted with a serial resonance circuit including the open stub and the inductance and the resonance frequency of the serial resonance circuit gives the central frequency of a bandgap. Accordingly, by increasing the stub length of the open stub including the conductor elements 121 and 161, it is possible to achieve a fall in the frequency of the bandgap range.

It is preferable that the conductor elements 121 and 161 constituting the microstrip line and the opposing plane be located close to each other. This is because as the distance between the conductor elements and the opposing plane becomes smaller, the characteristic impedance of the microstrip line becomes lower, thereby broadening the bandgap range. However, even when the conductor elements 121 and 161 are not made to approach the opposing plane, the substantial effect of the invention is not affected at all.

FIGS. 7(F) to 7(H) show examples where the connection member 122 and the connection member 162 are the same penetration via. In FIG. 7(F), the penetration via is connected to the power supply planes 141, 142, and 143 and passes through the openings of the ground planes 111 and 171. In FIG. 7 (G), the penetration via is connected to the ground plane 111 and 171 and passes through the openings of the power supply planes 141, 142, and 143. In FIG. 7 (H), the B layer 120 in which the conductor element 121 is formed is opposing the D layer 140 (the first layer) with the A layer 110 (the second layer) interposed therebetween. The F layer 160 in which the conductor element 161 is formed is opposing the D layer 140 (the first layer) with the G layer 170 (the third layer) interposed therebetween. The penetration vias (the connection members 122 and 162) are connected to the power supply planes 141, 142, and 143 and pass through the openings formed in the ground planes 111 and 171. The conductor elements 121 and 161 are opposing the ground planes 111 and 171 and are electrically connected to the penetration vias passing through the corresponding openings.

The structures shown in FIGS. 7(F) to 7(H) are modified examples of an open stub type EBG structure in which a microstrip line including the conductor elements 121 and 161 serves as an open stub. Specifically, the connection members 122 and 162 form inductance. On the other hand, in FIGS. 7(F) and 7(H), the conductor elements 121 and 161 are electrically coupled to the opposing ground planes 111 and 171 to form a microstrip line having the ground planes 111 and 171 as a return path. In FIG. 7(G), the conductor elements 121 and 161 are electrically coupled to the opposing power supply plane 141 (or 142 or 143) to form a microstrip line having the power supply plane 141 (or 142 or 143) as a return path. One end of the microstrip line is an open end and is configured to serve as an open stub.

Similarly to the open stub type EBG structure, the structures shown in FIGS. 7(F) to 7(H) can be expressed by an equivalent circuit in which a parallel plate is shunted with a serial resonance circuit including the open stub and the inductance and the resonance frequency of the serial resonance circuit gives the central frequency of a bandgap. Accordingly, by increasing the stub length of the open stub including the conductor elements 121 and 161, it is possible to achieve a fall in the frequency of the bandgap range.

It is preferable that the conductor elements 121 and 161 constituting the microstrip line and the opposing plane be located close to each other. This is because as the distance between the conductor elements and the opposing plane becomes smaller, the characteristic impedance of the microstrip line becomes lower, thereby broadening the bandgap range. However, even when the conductor elements 121 and 161 are not made to approach the opposing plane, the substantial effect of the invention is not affected at all.

By employing the configurations shown in FIGS. 7(F) to 7(H), it is possible to form an EBG structure in the first and second parallel plates using the penetration via. In general, a non-penetration via is formed by first processing a via for each layer and then stacking the layers, but a penetration via is formed by stacking all the layers, forming a through-hole with a drill, and then plating the inner surface of the through-hole. Accordingly, it is possible to reduce the manufacturing cost, compared with a case where a non-penetration via is used.

In FIG. 7, the shape of the transmission line is a spiral shape, but is not limited to this shape. For example, the shape of the transmission line may be a linear shape and may be a meandering shape.

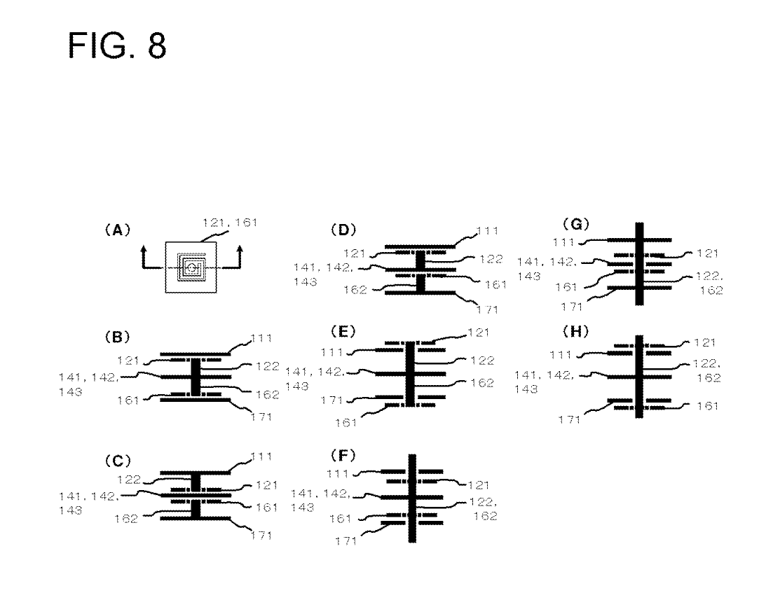

FIG. 8 (A) is a plan view illustrating an example of the conductor elements 121 and 161. The conductor elements 121 and 161 shown in the drawing are square conductors and have an opening. A spiral inductor of which one end is connected to the edge of the opening and the other end is connected to the connection member 122 or 162 is formed in the opening.

FIGS. 8(B) to 8(F) are cross-sectional views of the circuit board 100 around the conductor elements 121 and 161 shown in FIG. 8(A). Among these, FIGS. 8(B) to 8(D) show an example where the connection member 122 and the connection member 162 are formed of different members. In FIG. 8(B), the connection members 122 and 162 are connected to the power supply planes 141, 142, and 143. In FIG. 8(C), the connection member 122 is connected to the ground plane 111 and the connection member 162 is connected to the ground plane 171. In FIG. 8(D), the connection member 122 is connected to the power supply planes 141, 142, and 143, and the connection member 162 is connected to the ground plane 171. In FIG. 8(E), the B layer 120 in which the conductor element 121 is formed is opposing the D layer 140 (the first layer) with the A layer 110 (the second layer) interposed therebetween. The F layer 160 in which the conductor element 161 is formed is opposing the D layer 140 (the first layer) with the G layer 170 (the third layer) interposed therebetween. The connection members 122 and 162 are connected to the power supply planes 141, 142, and 143, and pass through the openings formed in the ground planes 111 and 171. The conductor elements 121 and 161 are opposing the ground planes 111 and 171 and are electrically connected to the connection members 122 and 162 passing through the openings.

The structures shown in FIGS. 8(B) to 8(E) can constitute an inductance-increased EBG structure in which inductance is increased by forming an inductor in the head part of a mushroom in a mushroom-like EBG structure as a basic structure. More specifically, in FIGS. 8(B) and 8(E), the conductor elements 121 and 161 correspond to the head part of a mushroom and form capacitance along with the opposing ground planes 111 and 171. In FIG. 8(C), the conductor elements 121 and 161 correspond to the head part of the mushroom and form capacitance along with the opposing power supply plane 141 (or 142 or 143). In FIG. 8(D), the conductor elements 121 and 161 correspond to the head part of the mushroom and form capacitance along with the opposing ground plane 111 and the opposing power supply plane 141 (or 142 or 143). On the other hand, the connection members 122 and 162 correspond to the stem part of a mushroom and form inductance along with the inductors formed in the conductor elements 121 and 161.

The inductance-increased EBG structure can be expressed by an equivalent circuit in which a parallel plate is shunted with a serial resonance circuit including the capacitance and the inductance and the resonance frequency of the serial resonance circuit gives the central frequency of a bandgap. Accordingly, by causing the conductor elements 121 and 161 to approach the opposing planes forming the capacitance to increase the capacitance or extending the length of the inductor to increase the inductance, it is possible to achieve a fall in the frequency of the bandgap range. However, even when the conductor elements 121 and 161 are not made to approach the opposing planes, the substantial effect of the invention is not affected at all.

FIGS. 8(F) to 8(H) show examples where the connection member 122 and the connection member 162 are the same penetration via. In FIG. 8(F), the penetration via is connected to the power supply planes 141, 142, and 143 and passes through the openings of the ground planes 111 and 171. In FIG. 8(G), the penetration via is connected to the ground plane 111 and 171 and passes through the openings of the power supply planes 141, 142, and 143. In FIG. 8(H), the B layer 120 in which the conductor element 121 is formed is opposing the D layer 140 (the first layer) with the A layer 110 (the second layer) interposed therebetween. The F layer 160 in which the conductor element 161 is formed is opposing the D layer 140 (the first layer) with the G layer 170 (the third layer) interposed therebetween. The penetration vias (the connection members 122 and 162) are connected to the power supply planes 141, 142, and 143 and pass through the openings formed in the ground planes 111 and 171. The conductor elements 121 and 161 are opposing the ground planes 111 and 171 and are electrically connected to the penetration vias passing through the corresponding openings.

The structures shown in FIGS. 8(F) to 8(H) are modified examples of the inductance-increased EBG structure in which inductance is increased by forming an inductor in the head part of a mushroom. Specifically, the connection members 122 and 162 correspond to the stem part of a mushroom and form inductance. On the other hand, in FIGS. 8(F) and 8(H), the conductor elements 121 and 161 correspond to the head part of a mushroom and form capacitance along with the opposing ground planes 111 and 171. In FIG. 8(G), the conductor elements 121 and 161 correspond to the head part of a mushroom and form capacitance along with the opposing power supply plane 141 (or 142 or 143).

Similarly to the mushroom-like EBG structure, the structures shown in FIGS. 8(F) to 8(H) can be expressed by an equivalent circuit in which a parallel plate is shunted with a serial resonance circuit including the capacitance and the inductance and the resonance frequency of the serial resonance circuit gives the central frequency of a bandgap. Accordingly, it is possible to achieve a fall in the frequency of the bandgap range by causing the conductor elements 121 and 161 to approach the opposing planes forming the capacitance to increase the capacitance or extending the length of the inductor to increase the inductance. However, even when the conductor elements 121 and 161 are not made to approach the opposing planes, the substantial effect of the invention is not affected at all.

By employing the configurations shown in FIGS. 8(F) to 8(H), it is possible to form an EBG structure in the first and second parallel plates using the penetration via. In general, a non-penetration via is formed by first processing a via for each layer and then stacking the layers, but a penetration via is formed by stacking all the layers, forming a through-hole with a drill, and then plating the inner surface of the through-hole. Accordingly, it is possible to reduce the manufacturing cost, compared with a case where a non-penetration via is used. In FIG. 8, the shape of the inductor is a spiral shape, but is not limited to this shape. For example, the shape of the transmission line may be a linear shape and may be a meandering shape.

When the examples shown in FIGS. 6(B) to 6(D), FIGS. 7(B) to 7(D), and FIGS. 8(B) to 8(D) are used, it is not necessary to form the openings, through which the connection members 122 and 162 pass, in the ground planes 111 and 171. Here, when the regions of the ground planes 111 and 171 opposing the conductor elements 121 and 161 are imperforate, noise does not leak from the region. Here, when pores (apertures) having a diameter sufficiently smaller than the wavelength of noise of the frequency band to be suppressed are formed in the regions opposing the conductor elements 121 and 161, the regions can be considered to be imperforate.

When the examples shown in FIGS. 6(E), 6(F), and 6(H), FIGS. 7(E), 7(F), and 7(H), and FIGS. 8(E), 8(F), and 8(H) are used, the ground planes 111 and 171 have openings through which the connection members 122 and 162 pass. However, when the openings have a diameter sufficiently smaller than the wavelength of noise of a frequency band to be suppressed, noise to be suppressed does not leak therefrom.

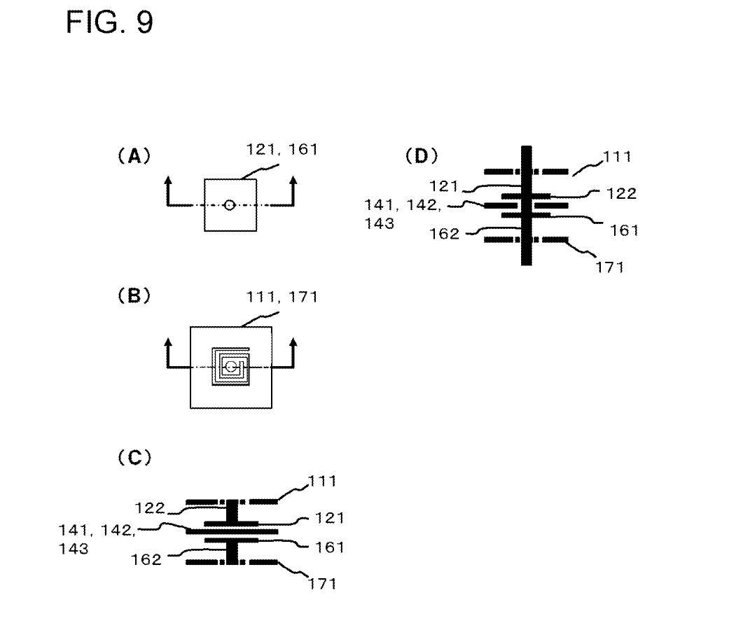

FIG. 9(A) is a plan view illustrating an example of the conductor elements 121 and 161. The conductor elements 121 and 161 have a square shape and are connected to the connection members 122 and 162. FIG. 9(B) is a plan view illustrating the regions of the ground planes 111 and 171 opposing the conductor elements 121 and 161. The regions shown in the drawing have an opening, and an inductor of which one end is connected to the edge of the opening and the other end is connected to the connection member 122 or 162 is formed in the opening.

FIGS. 9(C) and 9(D) are cross-sectional views of the circuit board 100 around the conductor elements 121 and 161 shown in FIG. 9(A). Among these, in FIG. 9(C), the connection member 122 and the connection member 162 are formed of different members. The connection member 122 is connected to the inductor formed in the opening of the ground plane 111 and the connection member 162 is connected to the inductor formed in the opening of the ground plane 171.

The structures shown in FIGS. 9(C) can constitute an inductance-increased EBG structure in which inductance is increased by forming an inductor in the ground planes 111 and 171 in a mushroom-like EBG structure as a basic structure. More specifically, in FIG. 9(C), the conductor elements 121 and 161 correspond to the head part of a mushroom and form capacitance along with the opposing power supply plane 141 (or 142 or 143). On the other hand, the connection members 122 and 162 correspond to the stem part of a mushroom and form inductance along with the inductors formed in the ground planes 111 and 171.

The inductance-increased EBG structure can be expressed by an equivalent circuit in which a parallel plate is shunted with a serial resonance circuit including the capacitance and the inductance and the resonance frequency of the serial resonance circuit gives the central frequency of a bandgap. Accordingly, by causing the conductor elements 121 and 161 to approach the opposing planes forming the capacitance to increase the capacitance or extending the length of the inductor to increase the inductance, it is possible to achieve a fall in the frequency of the bandgap range. However, even when the conductor elements 121 and 161 are not made to approach the opposing planes, the substantial effect of the invention is not affected at all.

In FIG. 9(D), the connection member 122 and the connection member 162 are formed of the same penetration via and pass through the openings of the power supply planes 141, 142, and 143. The penetration via is connected to the inductor formed in the opening of the ground plane 111 and the inductor formed in the opening of the ground plane 171.

The structures shown in FIGS. 9(D) can constitute an inductance-increased EBG structure in which inductance is increased by forming an inductor in the ground planes 111 and 171 in a mushroom-like EBG structure as a basic structure. More specifically, in FIG. 9(D), the conductor elements 121 and 161 correspond to the head part of a mushroom and form capacitance along with the opposing power supply plane 141 (or 142 or 143). On the other hand, the connection members 122 and 162 correspond to the stem part of a mushroom and form inductance along with the inductors formed in the ground planes 111 and 171.

The inductance-increased EBG structure can be expressed by an equivalent circuit in which a parallel plate is shunted with a serial resonance circuit including the capacitance and the inductance and the resonance frequency of the serial resonance circuit gives the central frequency of a bandgap. Accordingly, by causing the conductor elements 121 and 161 to approach the opposing planes forming the capacitance to increase the capacitance or extending the length of the inductor to increase the inductance, it is possible to achieve a fall in the frequency of the bandgap range. However, even when the conductor elements 121 and 161 are not made to approach the opposing planes, the substantial effect of the invention is not affected at all. In FIG. 9, the shape of the inductor is a spiral shape, but is not limited to this shap . For example, the shape of the inductor may be a linear shape and may be a meandering shape.

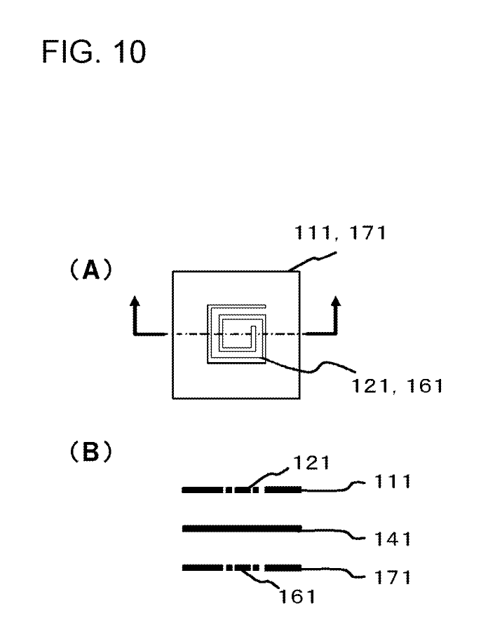

FIGS. 10 to 12 to be described below are examples where the conductor elements 121 and 161 are arranged in the A layer 110 (the second layer) in which the ground plane 111 is located or in the G layer 170 (the third layer) in which the ground plane 171 is located. That is, since the conductor elements 121 and 161 and the ground plane 111 or 171 are formed in the same layer, it is possible to reduce the thickness of the circuit board 100, compared with the above-mentioned examples. The configurations shown in FIGS. 10 to 12 do not need the connection members 122 and 162. In FIGS. 10 to 12, the upper stage and the lower stage of the power supply planes 141, 142, and 143 are symmetric, but both may not necessarily be symmetric. The conductor elements 121 or the conductor elements 161 may be arranged in one layer of the A layer 110 and the G layer 170.

FIG. 10(A) is a plan view illustrating an example of the conductor elements 121 and 161 formed in the ground planes 111 and 171. The ground planes 111 and 171 have openings. The conductor elements 121 and 161 include an island-like conductor formed in the opening and an inductor connecting the island-like conductor to the ground planes 111 and 171. In FIG. 10(A), the inductor spirally surrounds the island-like conductor, but the shape is not limited to this. For example, the inductor may have a linear shape and may have a meandering shape.

FIG. 10(B) is a cross-sectional view of the periphery of the conductor elements 121 and 161 taken along the sectional line marked in FIG. 10(A). The conductor elements 121 and 161 formed in the ground planes 111 and 171 are opposing the power supply planes 141, 142, and 143.

The structure shown in FIG. 10 is a modified example of a mushroom-like EBG structure. Here, since the head part and the stem part of a mushroom are formed in the openings of the ground planes 111 and 117, it is possible to reduce the number of layers necessary for constituting an EBG structure and it is thus possible to make the connection members 122 and 162 unnecessary. Specifically, the island-like conductor constituting the conductor element 121 or 161 corresponds to the head part of the mushroom and forms capacitance along with the opposing power supply plane 141 (or 142 or 143). The inductor constituting the conductor element 121 or 161 corresponds to the stem part of the mushroom and forms inductance.

Similarly to the mushroom-like EBG structure, the structure shown in FIG. 10 can be expressed by an equivalent circuit in which a parallel plate is shunted with a serial resonance circuit including the capacitance and the inductance and the resonance frequency of the serial resonance circuit gives the central frequency of a bandgap. Accordingly, it is possible to achieve a fall in the frequency of the bandgap range by causing the layer in which the island-like conductor is arranged to approach the opposing power supply plane forming the capacitance to increase the capacitance. However, even when the layer in which the island-like conductor is arranged is not made to approach the opposing power supply plane, the substantial effect of the invention is not affected at all.

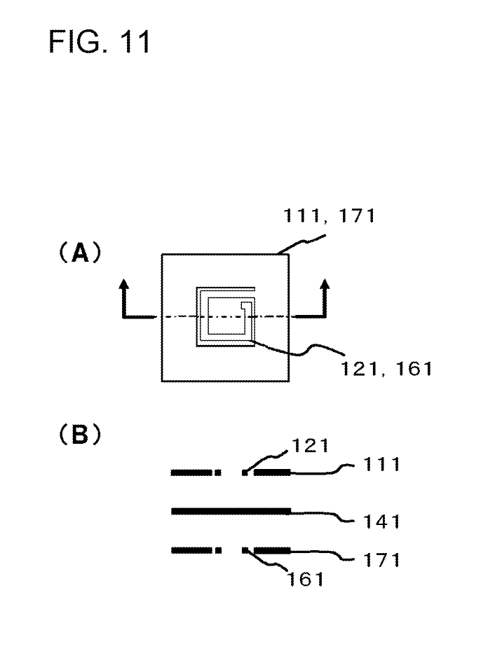

FIG. 11(A) is a plan view illustrating an example of the conductor elements 121 and 161 formed in the ground planes 111 and 171. The ground planes 111 and 171 have openings. The conductor element 121 or 161 is a transmission line which is formed in the corresponding opening and of which one end is connected to the edge of the opening and the other end is an open end not connected to the edge of the opening. In FIG. 11(A), the transmission line is shown to be spiral, but the transmission line is not limited to this shape. For example, the transmission line may have a linear shape and may have a meandering shape.

FIG. 11(B) is a cross-sectional view of the periphery of the conductor elements 121 and 161 taken along the sectional line marked in FIG. 11(A). The conductor elements 121 and 161 formed in the ground planes 111 and 171 are opposing the power supply planes 141, 142, and 143.

The structure shown in FIG. 11 is a modified example of an open stub type EBG structure. Here, since the transmission lines serving as an open stub are formed in the openings of the ground planes 111 and 171, it is possible to reduce the number of layers necessary for constituting an EBG structure and it is thus possible to make the connection members 122 and 162 unnecessary. Specifically, by electrically coupling the conductor elements 121 and 161 to the opposing power supply plane 141 (or 142 or 143), a microstrip line having the power supply plane 141 (or 142 or 143) as a return path is formed. An end of the microstrip line is an open end and is configured to serve as an open stub.

The open stub type EBG structure can be expressed by an equivalent circuit in which a parallel plate is shunted with a serial resonance circuit including the open stub and the inductance and the resonance frequency of the serial resonance circuit gives the central frequency of a bandgap. Accordingly, by increasing the stub length of the open stub including the conductor elements 121 and 161, it is possible to achieve a fall in the frequency of the bandgap range. It is preferable that the conductor elements 121 and 161 constituting the microstrip line and the opposing plane be located close to each other. This is because as the distance between the conductor elements and the opposing power supply plane becomes smaller, the characteristic impedance of the microstrip line becomes lower, thereby broadening the bandgap range. However, even when the conductor elements 121 and 161 are not made to approach the opposing power supply plane, the substantial effect of the invention is not affected at all.

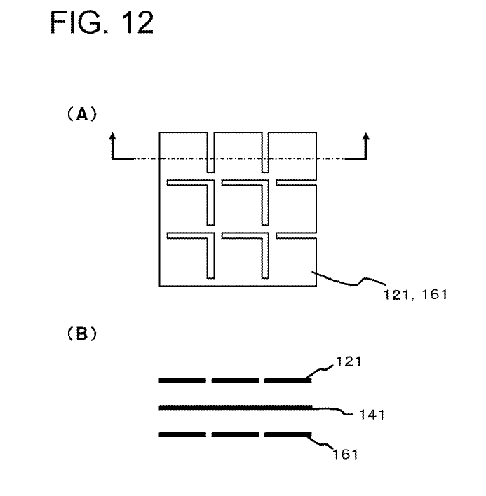

FIG. 12(A) is a plan view illustrating an example of the conductor elements 121 and 161 formed in the ground planes 111 and 171. The conductor elements 121 and 161 are plural island-like conductors formed in some of the ground planes 111 and 171 and the neighboring island-like conductors are electrically connected to each other.

FIG. 12(B) is a cross-sectional view of the periphery of the conductor elements 121 and 161 taken along the sectional line marked in FIG. 12(A). The conductor elements 121 and 161 formed in the ground planes 111 and 171 are opposing the power supply planes 141, 142, and 143.

The structure shown in FIG. 12 serves as an EBG structure by electrically coupling the neighboring island-like conductors to each other to form capacitance and causing joining portions of the island-like conductors to form inductance. In the EBG structure shown in FIG. 12, the resonance frequency of a serial resonance circuit including the capacitance and the inductance gives the central frequency of a bandgap. Accordingly, by reducing the gap between the island-like conductors to increase the capacitance or extending the length of the joining portion to increase the inductance, it is possible to achieve a fall in the frequency of the bandgap range.

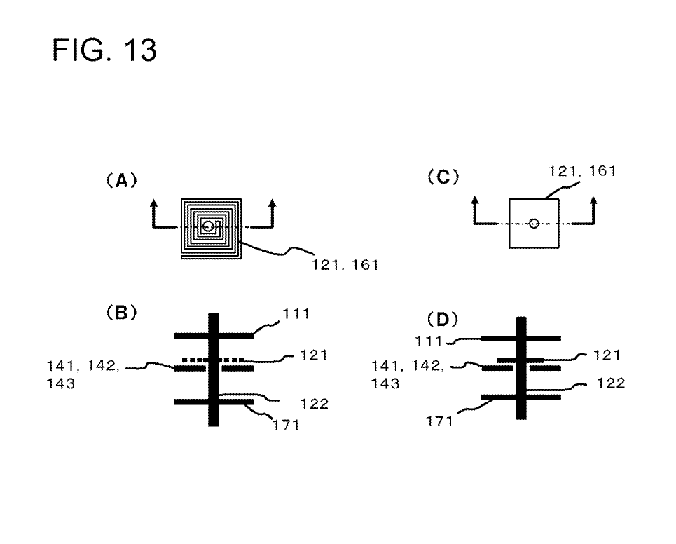

FIG. 13(A) is a plan view illustrating an example of the conductor element 121. The conductor element 121 shown in the drawing is a spiral transmission line formed in a planar direction and is electrically coupled to the opposing power supply plane 141 (or 142 or 143) to form a microstrip line having the power supply plane 141 (or 142 or 143) as a return path. An end of the conductor element 121 is electrically connected to the connection member 122 and the other end thereof is an open end.

FIG. 13(B) is a cross-sectional view of the periphery of the conductor elements 121 taken along the sectional line marked in FIG. 13(A). In FIG. 13(B), the connection member 122 is formed as a penetration via, and the penetration via is connected to the conductor element 121 and the ground plane 111 or 171 and passes through the openings of the power supply planes 141, 142, and 143.

In the configuration shown in FIGS. 13(A) and 13(B), the conductor element 121 forms an open stub type EBG structure along with the ground plane 111, the power supply planes 141, 142, and 143, and the connection member 122, thereby suppressing noise propagating in the first parallel plate. In addition, the conductor element 121 forms an open stub type EBG structure along with the ground plane 171, the power supply planes 141, 142, and 143, and the connection member 122, thereby suppressing noise propagating in the second parallel plate. That is, even when the number of the B layers 120 in which the conductor elements 121 is formed is equal to the number of the D layer 140 in which the power supply planes 141, 142, and 143 are formed, it is possible to constitute an EBG structure for the first and second parallel plates. Accordingly, since the conductor element 161 is made to be unnecessary in comparison with the configuration shown in FIG. 7(G), it is possible to improve the degree of freedom in wiring in the F layer 160. When it is not necessary to form lines in the F layer 160, it is possible to remove the F layer 160 and it is thus possible to reduce the thickness of the circuit board 100. FIG. 13(B) shows an example where the conductor elements are arranged in the B layer 120, but a configuration in which the conductor elements are arranged in the F layer 160 instead of the B layer 120 can be considered. In this case, it is similarly possible to suppress noise propagating in the first and second parallel plate.

In the structure shown in FIGS. 13(A) and 13(B), completely similarly to the other open stub type EBG structure, it is possible to achieve a fall in the frequency of the bandgap range by extending the stub length of the open stub including the conductor element 121. It is preferable that the conductor elements 121 constituting the microstrip line and the opposing plane be located close to each other. This is because as the distance between the conductor elements and the opposing plane becomes smaller, the characteristic impedance of the microstrip line becomes lower, thereby broadening the bandgap range. However, even when the conductor elements 121 and 161 are not made to approach the opposing plane, the substantial effect of the invention is not affected at all. In FIG. 13, the shape of the transmission line is a spiral shape, but is not limited to this shape. For example, the shape of the transmission line may be a linear shape and may be a meandering shape.

FIG. 13(C) is a plan view illustrating an example of the conductor element 121. The conductor element 121 shown in the drawing has a square shape and is electrically connected to the connection member 122.

FIG. 13(D) is a cross-sectional view of the periphery of the conductor element 121 taken along the sectional line marked in FIG. 13(C). In FIG. 13(D), the connection member 122 is formed as a penetration via, and the penetration via is connected to the ground plane 111 or 171 and passes through the opening of the power supply plane 141 (or 142 or 143).

In the configuration shown in FIGS. 13(C) and 13(D), the conductor element 121 forms a mushroom-like EBG structure along with the ground plane 111, the power supply planes 141, 142, and 143, and the connection member 122, thereby suppressing noise propagating in the first parallel plate. In addition, the conductor element 121 forms a mushroom-like EBG structure along with the ground plane 171, the power supply planes 141, 142, and 143, and the connection member 122. That is, even when the number of the B layers 120 in which the conductor elements 121 is formed is equal to the number of the D layer 140 in which the power supply planes 141, 142, and 143 are formed, it is possible to constitute an EBG structure for the first and second parallel plates. Accordingly, since the conductor element 161 is made to be unnecessary in comparison with the configuration shown in FIG. 6(G), it is possible to improve the degree of freedom in wiring in the F layer 160. When it is not necessary to form lines in the F layer 160, it is possible to remove the F layer 160 and it is thus possible to reduce the thickness of the circuit board 100. FIG. 13(D) shows an example where the conductor elements are arranged in the B layer 120, but a configuration in which the conductor elements are arranged in the F layer 160 instead of the B layer 120 can be considered. In this case, it is similarly possible to suppress noise propagating in the first and second parallel plate.

The advantageous effects of the first embodiment will be described below. Like the electronic device 181 to be mounted in this embodiment, an electronic device generally requires plural source voltages. Accordingly, the power supply planes 141, 142, and 143 of the circuit board 100 are separated with the gaps 147 interposed therebetween and the regions having different potentials are connected to the electronic device 181, whereby plural source voltages are supplied thereto. In this configuration, without blocking noise radiated from the gaps 147, it is not possible to achieve a satisfactory noise countermeasure. Therefore, in this embodiment, the gaps 147 are surrounded with the ground planes 111 and 171 and the EBG structures including unit cells repeatedly arranged. Accordingly, noise generated from the electronic device 181 propagates in at least one of a space between any one of the power supply planes 141, 142, and 143 and the ground plane 111 and a space between any one of the power supply planes 141, 142, and 143 and the ground plane 171 and is radiated from the gaps 147 to the other side, it is possible to block the radiated noise by the use of the ground plane 111 or the ground plane 171. In the space between any one of the plural conductor elements 121 repeatedly arranged and the ground plane 111 or the ground plane 171, it is possible to block the noise.

More specifically, the noise generated in the electronic device 181 propagates in at least one of the first parallel plate including the ground plane 111 and the power supply plane 141 (or 142 or 143) and the second parallel plate including the ground plane 171 and the power supply plane 141 (or 142 or 143) through the connection members 182, 183, and 184, and a part of the noise is radiated from the gaps 147 between the power supply planes to the other parallel plate. In this embodiment, since the ground planes 111 and 171 and the EBG structure including unit cells repeatedly arranged surround the gaps 147 between the power supply planes to block the propagation thereof to the outside, it is possible to prevent the noise radiated from the gaps 147 from leaking to the outside of the circuit board 100.

Since the frequency of noise generated from the electronic device 181 is included in the bandgap range of the EBG structure formed in this embodiment, it is possible to achieve a better noise suppressing effect.

### Second Embodiment

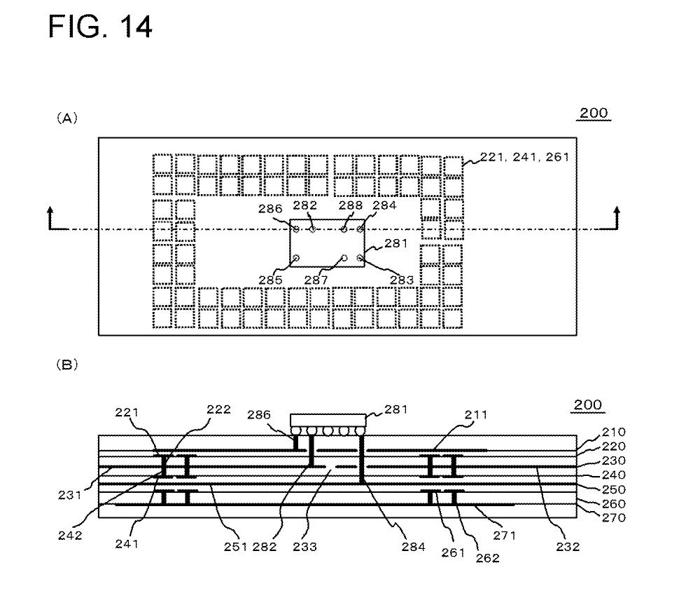

FIG. 14 shows a plan view and a cross-sectional view of a circuit board 200 according to a second embodiment of the invention. More specifically, FIG. 14(A) is a plan view of the circuit board 200 and FIG. 14(B) is a cross-sectional view of the circuit board 200 taken along the indicated sectional line in FIG. 14(A). The circuit board 200 is a multi-layered board including at least an A layer 210, a B layer 220, a C layer 230, a D layer 240, an E layer 250, an F layer 260, and a G layer 270 which are opposing each other. The circuit board 200 may include a layer other than the seven layers. For example, a dielectric layer may be located between the layers. The circuit board 200 may further include holes or vias not shown in the drawing without conflicting with the configuration of the invention. Signal lines may be arranged in the seven layers without conflicting with the configuration of the invention.

An electronic device 281 is mounted on the surface of the circuit board 200, and the circuit board includes a connection member 282 connecting the electronic device 281 to a power supply plane 231, a connection member 283 connecting the electronic device 281 to a power supply plane 232, a connection member 284 connecting the electronic device 281 to a power supply plane 251, and a connection member 285 connecting the electronic device 281 to a power supply plane 252. The circuit board 200 includes a connection member 286 connecting the electronic device 281 to a ground plane 211 and a connection member 287 connecting the electronic device 281 to a ground plane 271. The circuit board 200 includes a connection member 288 connecting the electronic device 281 to a signal line 263. In this embodiment, the electronic device 281 is connected to all the power supply planes 231, 232, 251, and 252, but has only to be connected to at least one thereof.

In FIG. 14(A), since conductor elements 221, 241, and 261 are located under the uppermost layer, they are indicated by dotted lines. Since the positions of the conductor elements overlap in a plan view, a single square represents the conductor element 221, the conductor element 241, and the conductor element 261.

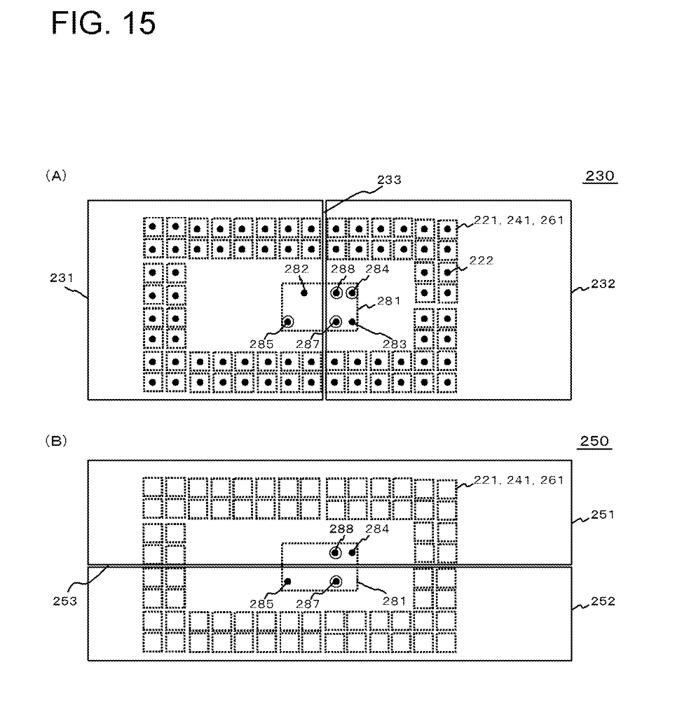

FIG. 15 is a diagram illustrating the C layer 230 and the E layer 250 of the circuit board 200. In the C layer 230 (the first layer), the power supply planes 231 and 232 (the plural first conductors) are arranged with a gap 233 interposed therebetween. In the D layer 240 (the first layer), the power supply planes 251 and 252 (the plural first conductors) are arranged with a gap 253 interposed therebetween. Since the gap 233 and the gap 253 are filled with an insulator, the power supply planes 231, 232, 251, and 252 are insulated from each other, whereby different potentially can be supplied to the power supply planes.

The power supply plane 231, the power supply plane 232, the power supply plane 251, and the power supply plane 252 are connected to the connection member 282, the connection member 283, the connection member 284, and the connection member 285, respectively, and are thus electrically connected to the electronic device 281. The connection members 284, 285, and 287 pass through the openings formed in the power supply planes 231 and 232 and are insulated from the power supply planes 231 and 232. The connection member 287 passes through the opening formed in the power supply plane 252 and is insulated from the power supply plane 252.

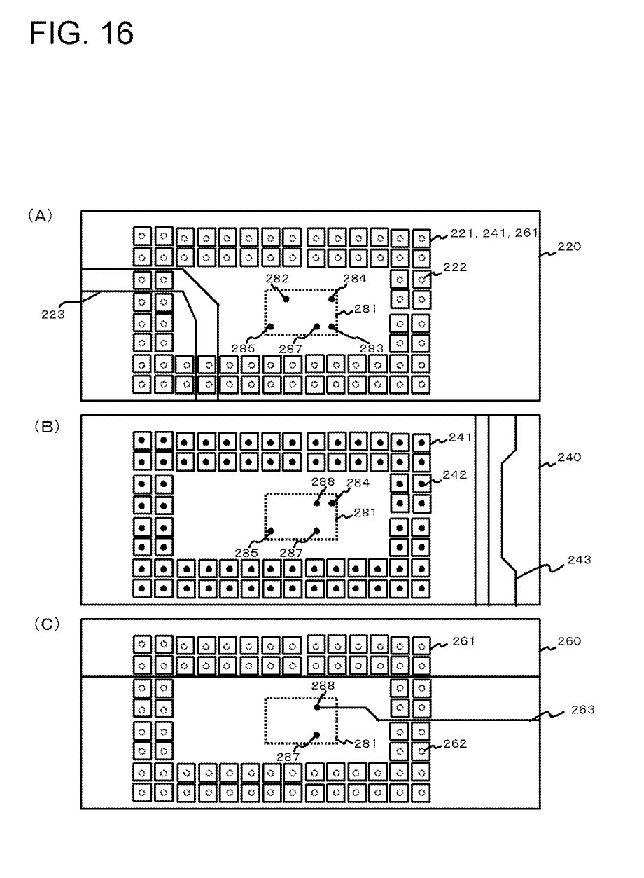

FIG. 16 is a diagram illustrating the B layer 220, the D layer 240, and the F layer 260 of the circuit board 200. In the B layer 220, plural conductor elements 221 (the second conductors) are repeatedly arranged to surround a first region including at least some of the gaps 233 and 253 and connection points (connection points to the connection members 282, 283, 284, and 285) on the power supply planes 231, 232, 251, and 252 to the electronic device 281. A signal line 223 is further arranged in the B layer 220. In the D layer 240, plural conductor elements 241 (the second conductors) are repeatedly arranged to surround the first region. A signal line 243 is further arranged in the D layer 240. In the F layer 260, plural conductor elements 261 (the second conductors) are repeatedly arranged to surround the first region. A signal line 263 is further arranged in the F layer 260. The arrangement patterns of the signal lines 223, 243, and 263 are not limited to the shown patterns, but the signal lines may be arranged as long as they do not come in contact with the conductor elements 221, 241, and 261. The conductor elements 221, 241, and 261 are opposing any of the power supply planes 231 and 232 or the power supply planes 251 and 252.

The conductor element 221 is a conductor formed in an island shape in the B layer 220 and is connected to any one of the power supply planes 231 and 232 through the connection member 222. The conductor element 241 is a conductor formed in an island shape in the D layer 240 and is connected to any one of the power supply planes 231 and 232 through the connection member 242. The conductor element 261 is a conductor formed in an island shape in the F layer 260 and is connected to the ground plane 271 through the connection member 262.

In this embodiment, an example where the conductor elements 221, 241, and 261 are arranged in two lines is described, but may be arranged in a single line as in the first embodiment, or may be arranged in three or more lines, or the conductor elements 221, 241, and 261 may be arranged in the overall first region.

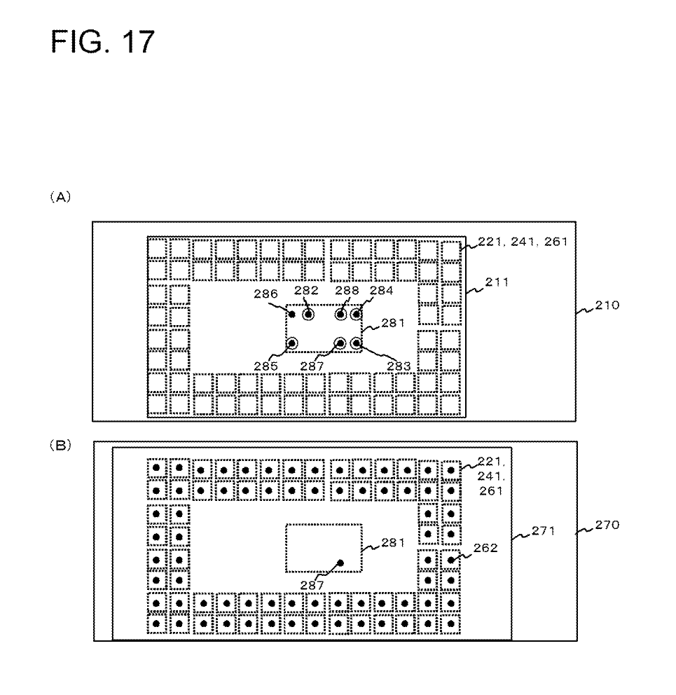

FIG. 17 is a diagram illustrating the A layer 210 and the G layer 270 of the circuit board 200. The ground plane 211 (the third conductor) is a sheet-like conductor, is located in the A layer 210 (the second layer) which is a layer above the C layer 230, and extends in a second region including a region opposing the first region and a region opposing the conductor elements 221. The ground plane 271 (the fourth conductor) is a sheet-like conductor, is located in the G layer 270 (the third layer) which is a layer below the E layer 250, and extends in a third region including a region opposing the first region and a region opposing the conductor elements 241.

The ground plane 211 or the ground plane 271 is supplied with a reference potential by grounding or the like. Since the connection members 282, 283, 284, 285, and 287 pass through the openings formed in the ground plane 211 and are insulated from the ground plane 211.

In the circuit board 200, three noise propagation paths of a first parallel plate including the ground plane 211 and the power supply plane 231 (or 232), a second parallel plane including the power supply plane 231 (or 232) and the power supply plane 251 (or 252), and a third parallel plate including the power supply plane 251 (or 252) and the ground plane 271 can be considered.

By employing this configuration, the conductor element 221 constitutes a unit cell of an EBG structure along with the opposing power supply plane 231 (or 232), the opposing ground plane 211, and the connection member 222. By using the EBG structure in which the unit cells are repeatedly arranged, it is possible to suppress noise propagating in the first parallel plate. The conductor element 241 constitutes a unit cell of an EBG structure along with the opposing power supply plane 231 (or 232), the opposing power supply plane 251 (or 252), and the connection member 242. By using the EBG structure in which the unit cells are repeatedly arranged, it is possible to suppress noise propagating in the second parallel plate. The conductor element 261 constitutes a unit cell of an EBG structure along with the opposing power supply plane 251 (or 252), the opposing ground plane 271, and the connection member 262. By using the EBG structure in which the unit cells are repeatedly arranged, it is possible to suppress noise propagating in the third parallel plate. It is preferable that each EBG structure include the frequency of noise generated from the electronic device 281 in the bandgap range thereof. The unit cell of the EBG structure constructed in the circuit board 200 according to this embodiment is a structure including the connection member 222 or the connection member 262, but is not limited to this configuration. That is, the circuit board 200 may not necessarily have the connection member in an interlayer between the ground plane 211 and the power supply plane 231 (or 232) or an interlayer between the ground plane 271 and the power supply plane 251 (or 252). Unit cells of various EBG structures applicable to the circuit board 200 will be described later.

By adjusting the gaps between the A layer 210 to the G layer 270, the thickness of the connection members 222, 242, and 262, the mutual gap of the conductor elements 221, the mutual gap of the conductor elements 241, the mutual gap of the conductor elements 261, and the like, it is possible to set the frequency band to be suppressed to a desired value.

As described above, the mutual gaps of the conductor elements 221, 241, and 261 repeatedly arranged are parameters used to determine the characteristics of the EBG structure and are preferably constant. The mutual gap between the conductor elements 221, the mutual gap between the conductor elements 241, and the mutual gap between the conductor elements 261 may not necessarily match each other.

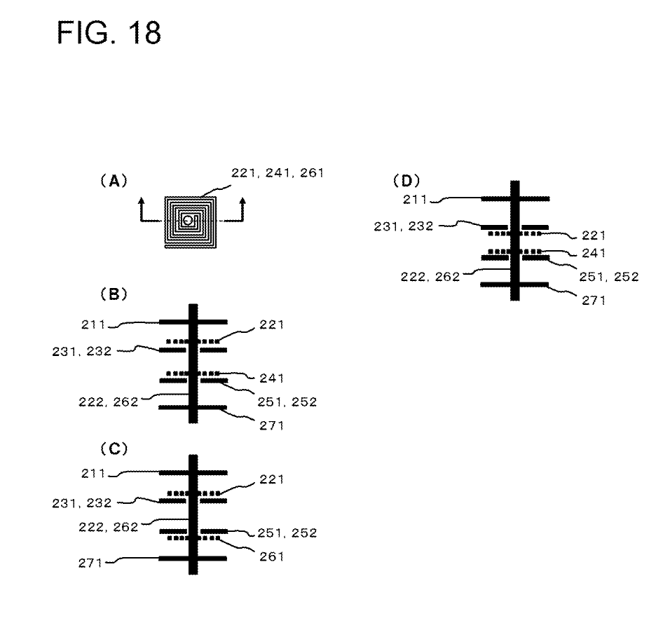

The shapes or the positions of the conductor elements 221, 241, and 261 or the connection members 222 and 252 shown in FIGS. 14 to 17 are only examples, and various examples can be employed as long as they can constitute an EBG structure. The most examples can be constructed by combining some examples shown in FIGS. 6 to 13. The examples shown in FIGS. 18 to 21 cannot be constructed by combinations of the above-mentioned modified examples.

FIGS. 18 to 21 are diagrams illustrating the shapes or the positions of the conductor elements 221, 241, and 261 or the connection members 222, 242, and 262. FIGS. 18 to 21 focus on the single conductor elements 221, 241, and 261 and shows an enlarged view of the periphery thereof. The structures shown in FIGS. 18 to 21 constitute a single unit cell or plural unit cells, and the circuit board 200 includes one of the unit cells or a combination thereof.

FIG. 18(A) is a plan view illustrating an example of the conductor elements 221, 241, and 261. The conductor elements 221, 241, and 261 shown in the drawing are spiral transmission lines formed in a planar direction, where one end thereof is connected to the connection members 222, 242, and 262 and the other end thereof is an open end. In FIG. 18(A), the transmission lines have a spiral shape, but are not limited to this shape. For example, the transmission lines may have a linear shape and may have a meandering shape.

FIGS. 18(B) to 18(D) are cross-sectional views of the periphery of the conductor elements 221, 241, and 261 taken along the sectional line marked in FIG. 18(A). In FIGS. 18(B) to 18(D), the connection member 222 and the connection member 262 are formed as a part of the same penetration via. The penetration via is connected to the ground plane 211 or 271 and passes through the openings of the power supply planes 231, 232, 251, and 252.

In the configuration shown in FIGS. 18(B) to 18(D), a conductor element is disposed for each opening formed in the power supply plane 231 (or 232) and the power supply plane 251 (or 252) so as for the penetration via to pass therethrough and each conductor element is electrically coupling to the opposing power supply plane to form a microstrip line having the opposing power supply plane as a return path. An end of the microstrip line is an open end and is configured to serve as an open stub.

By employing the above-mentioned configuration, the number of layers in which the conductor elements 221, 241, and 261 are formed is equal to the number of layers in which the power supply planes 231, 232, 251, and 252 are formed, and it is possible to reduce the number of conductor elements in comparison with the configuration shown in FIG. 14 and to construct an open stub type EBG structure for the first, second, and third parallel plates. Accordingly, since the mounting area of the conductor elements can be reduced in comparison with the configuration shown in FIG. 14, it is possible to improve the degree of freedom in arranging interconnects. When it is not necessary to form the interconnects, it is possible to reduce the number of layers in which the conductor elements are arranged and thus to reduce the thickness of the circuit board 200.

In the structure shown in FIG. 18, completely similarly to the other open stub type EBG structure, it is possible to achieve a fall in the frequency of the bandgap range by extending the stub length of the open stub including the conductor element 221, 241, or 261. It is preferable that the conductor elements 221, 241, and 261 constituting the microstrip line and the opposing plane be located close to each other. This is because as the distance between the conductor elements and the opposing plane becomes smaller, the characteristic impedance of the microstrip line becomes lower, thereby broadening the bandgap range. However, even when the conductor elements 221, 241, and 261 are not made to approach the opposing plane, the substantial effect of the invention is not affected at all.

Specifically, FIG. 18(B) shows an example where an EBG structure is formed between the A layer 210 and the G layer 270 even when the F layer 260 in which the conductor element 261 is formed is removed from the circuit board 200. Here, the conductor element 221 is located closer to the C layer 230 than the A layer 210 and the conductor element 241 is located closer to the E layer 250 than the C layer 230. FIG. 18(C) shows an example where an EBG structure is formed between the A layer 210 and the G layer 270 even when the D layer 240 in which the conductor element 241 is formed is removed from the circuit board 200. Here, the conductor element 221 is located closer to the C layer 230 than the A layer 210 and the conductor element 261 is located closer to the E layer 250 than the G layer 270. In FIG. 18(D), the B layer 220 in the example shown in FIG. 18(B) is located as an interlayer between the C layer 230 and the D layer 240. Here, the conductor element 221 is located closer to the C layer 230 than the D layer 240 and the conductor element 241 is located closer to the E layer 250 than the B layer 220.

The examples where an open stub type EBG structure is formed are described above with reference to FIGS. 18(A) to 18(D), but other types of EBG structures can be employed by employing conductor elements 261 having other shapes. That is, a modified example of a mushroom-like EBG structure is obtained by employing the conductor element 261 shown in FIG. 6(A) and a modified example of an inductance-increased EBG structure is obtained by employing the conductor element 261 shown in FIG. 8(A). These modified examples do not affect the substantial effects of the invention at all.

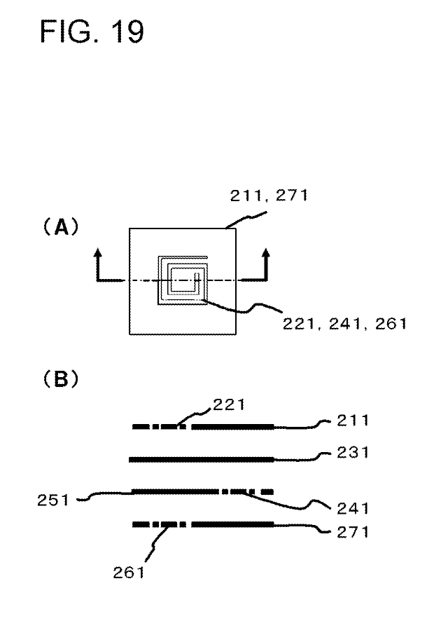

FIG. 19(A) is a plan view illustrating an example of the conductor elements 221, 241, and 261 formed in the ground planes 211 and 271 and the power supply planes 251 and 252. The ground planes 211 and 271 or the power supply planes 251 and 252 have openings. The conductor elements 221, 241, and 261 include an island-like conductor formed in the corresponding opening and an inductor connecting the island-like conductor to the ground planes 211 and 271 or the power supply planes 251 and 252. In FIG. 19(A), the inductor spirally surrounds the island-like conductor, but the shape thereof is not limited to this. For example, the inductor may have a linear shape and may have a meandering shape.

FIG. 19(B) is a cross-sectional view of the periphery of the conductor elements 221, 241, and 261 taken along a sectional line marked in FIG. 19(A). The conductor element 221 is formed in the ground plane 211, the conductor element 241 is formed in the power supply planes 251 and 252, and the conductor element 261 is formed in the ground plane 271. The ground plane 211 (the conductor element 221), the power supply planes 231 and 232, the power supply planes 251 and 252 (the conductor element 241), and the ground plane 271 are opposing each other. The structure shown in FIG. 19 basically has a mushroom-like EBG structure. Here, since the head part and the stem part of a mushroom are formed in the openings of the ground planes 211 and 271 and the power supply plane 251, it is possible to reduce the number of layers necessary for constituting an EBG structure and it is thus possible to make the connection members 222 and 262 unnecessary. Specifically, the island-like conductors constituting the conductor elements 221, 241, and 261 correspond to the head part of the mushroom and forms capacitance along with the opposing planes. The inductors constituting the conductor elements 221, 241, and 261 correspond to the stem part of the mushroom and forms inductance.

Similarly to the mushroom-like EBG structure, the structure shown in FIG. 19 can be expressed by an equivalent circuit in which a parallel plate is shunted with a serial resonance circuit including the capacitance and the inductance and the resonance frequency of the serial resonance circuit gives the central frequency of a bandgap. Accordingly, it is possible to achieve a fall in the frequency of the bandgap range by causing the layer in which the island-like conductor is arranged to approach the opposing plane forming the capacitance to increase the capacitance. However, even when the layer in which the island-like conductor is arranged is not made to approach the opposing plane, the substantial effect of the invention is not affected at all.

The conductor elements 221, 241, and 261 shown in FIG. 19(A) are opposing imperforate conductors to form an EBG structure. Accordingly, it is preferable that the conductor elements 221 be opposing an imperforate region on the power supply plane 231, the conductor elements 241 be opposing an imperforate region on the power supply plane 231, and the conductor elements 261 be opposing an imperforate region on the power supply plane 251. Here, the positions of the conductor elements 241 and the positions of the conductor elements 261 do not match each other in a plan view. When pores (apertures) having a diameter sufficiently smaller than the wavelength of noise of a frequency band to be suppressed are formed in the region opposing the conductor elements 221, 241, and 261, this can be considered to be imperforate. In the configuration shown in FIG. 19, the conductor elements 221, 241, and 261 and the signal lines 223, 243, and 263 can be formed in the same layer, but this is on the premise that the signal lines 223, 243, and 263 do not come in contact with the ground plane 211 or 271 or the power supply plane 251.

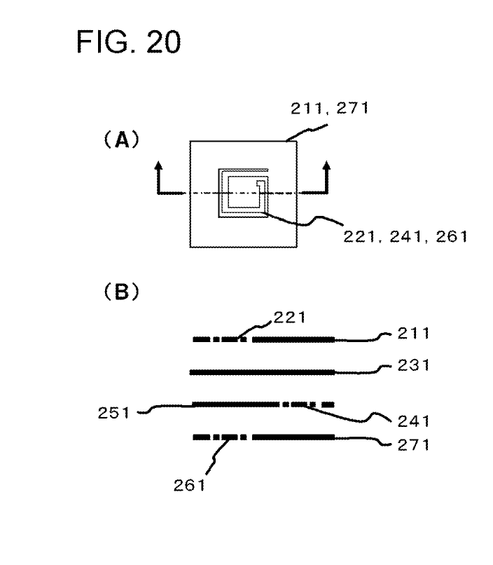

FIG. 20(A) is a plan view illustrating an example of the conductor elements 221, 241, and 261 formed in the ground planes 211 and 271 or the power supply planes 251 and 252. The ground planes 211 and 271 or the power supply planes 251 and 252 have openings. The respective conductor elements 221, 241, and 261 are a transmission line which is formed in the corresponding opening and of which one end is connected to the edge of the opening and the other end is an open end not connected to the edge of the opening. In FIG. 20(A), the transmission line is shown to be spiral, but the transmission line is not limited to this shape. For example, the transmission line may have a linear shape and may have a meandering shape.

FIG. 20(B) is a cross-sectional view of the circuit board 200 in the vicinity of the conductor elements 221, 241, and 261 shown in FIG. 20(A). The conductor elements 221 are formed in the ground plane 211, the conductor elements 241 are formed in the power supply planes 251 and 252, and the conductor elements 261 are formed in the ground plane 271. The ground plane 211 (the conductor elements 221), the power supply planes 231 and 232, the power supply planes 251 and 252 (the conductor elements 241), and the ground plane 271 (the conductor elements 261) are opposing each other.

The structure shown in FIG. 20 basically has an open stub type EBG structure. Here, since the transmission lines serving as an open stub are formed in the openings of the ground planes 211 and 271 and the power supply plane 251, it is possible to reduce the number of layers necessary for constituting an EBG structure and it is thus possible to make the connection members 222 and 262 unnecessary. Specifically, the conductor elements 221, 241, and 261 are electrically coupled to the opposing planes to form a microstrip line. An end of the microstrip line is an open end and is configured to serve as an open stub. In the structure shown in FIG. 20, completely similarly to the other open stub type EBG structures, it is possible to achieve a fall in the frequency of the bandgap range by extending the stub length of the open stub including the conductor elements 221, 241, and 261. It is preferable that the conductor elements 221, 241, and 261 constituting the microstrip line and the opposing plane be located close to each other. This is because as the distance between the conductor elements and the opposing plane becomes smaller, the characteristic impedance of the microstrip line becomes lower, thereby broadening the bandgap range. However, even when the conductor elements 221, 241, and 261 are not made to approach the opposing plane, the substantial effect of the invention is not affected at all.

The conductor elements 221, 241, and 261 shown in FIG. 20(A) are opposing imperforate conductors to form an EBG structure. Accordingly, it is preferable that the conductor elements 221 be opposing an imperforate region on the power supply plane 231, the conductor elements 241 be opposing an imperforate region on the power supply plane 231, and the conductor elements 261 be opposing an imperforate region on the power supply plane 251. Here, the positions of the conductor elements 241 and the positions of the conductor elements 261 do not match each other in a plan view.

When pores (apertures) having a diameter sufficiently smaller than the wavelength of noise of a frequency band to be suppressed are formed in the region opposing the conductor elements 221, 241, and 261, this can be considered to be imperforate. In the configuration shown in FIG. 20, the conductor elements 221, 241, and 261 and the signal lines 223, 243, and 263 can be formed in the same layer, but this is on the premise that the signal lines 223, 243, and 263 do not come in contact with the ground plane 211 or 271 or the power supply plane 251.

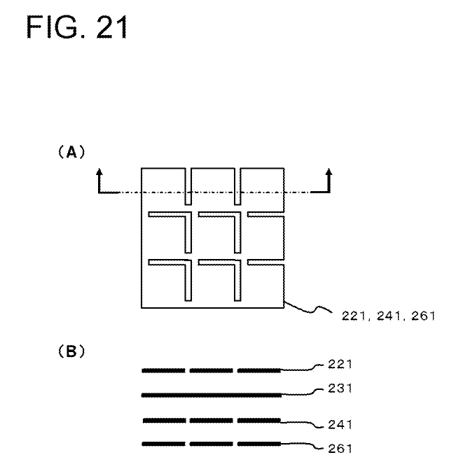

FIG. 21(A) is a plan view illustrating an example of the conductor elements 221, 241, and 261 formed in the ground planes 211 and 271 or the power supply planes 251 and 252. The conductor elements 221, 241, and 261 are plural island-like conductors formed in some of the ground planes 211 and 271 or the power supply planes 251 and 252 and the neighboring island-like conductors are electrically connected to each other.

FIG. 21(B) is a cross-sectional view of the periphery of the conductor elements 221, 241, and 261 taken along the sectional line marked in FIG. 21(A). The conductor elements 221, 241, and 261 formed in the ground planes 211 and 271 or the power supply planes 251 and 252 are opposing the planes. The structure shown in FIG. 21 serves as an EBG structure by electrically coupling the neighboring island-like conductors to each other to form capacitance and causing joining portions of the island-like conductors to form inductance. In the EBG structure shown in FIG. 21, the resonance frequency of a serial resonance circuit including the capacitance and the inductance gives the central frequency of a bandgap. Accordingly, by reducing the gap between the island-like conductors to increase the capacitance or extending the length of the joining portion to increase the inductance, it is possible to achieve a fall in frequency of the bandgap range.

In the configuration shown in FIG. 21, the conductor elements 221, 241, and 261 and the signal lines 223, 243, and 263 can be formed in the same layer, but this is on the premise that the signal lines 223, 243, and 263 do not come in contact with the ground planes 211 and 271 or the power supply planes 251 and 252.

FIGS. 19 to 21 show an example where the conductor elements 241 are formed in a single layer (the E layer 250) among the plural layers (the C layer 230 and the E layer 250) in which the power supply planes 231, 232, 251, and 252, but the conductor elements may be formed in two layers (the C layer 230 and the E layer 250). When the number of layers in which the power supply planes are formed is three or more, the conductor elements may be formed in the three or more layers.

The advantageous effects of the second embodiment will be described below. In this embodiment, the circuit board 200 is described above in which the number of layers in which the power supply planes 231, 232, 251, and 252 are formed is two or more. By employing this configuration, the circuit board 200 can prevent the leakage of noise propagating in the A layer 210 to the F layer 260, similarly to the circuit board 100 according to the first embodiment.

Since the signal lines 223, 243, and 263 are arranged in the same layer as the conductor elements 221, 241, and 261, it is possible to realize more space-saving wiring.

### Third Embodiment

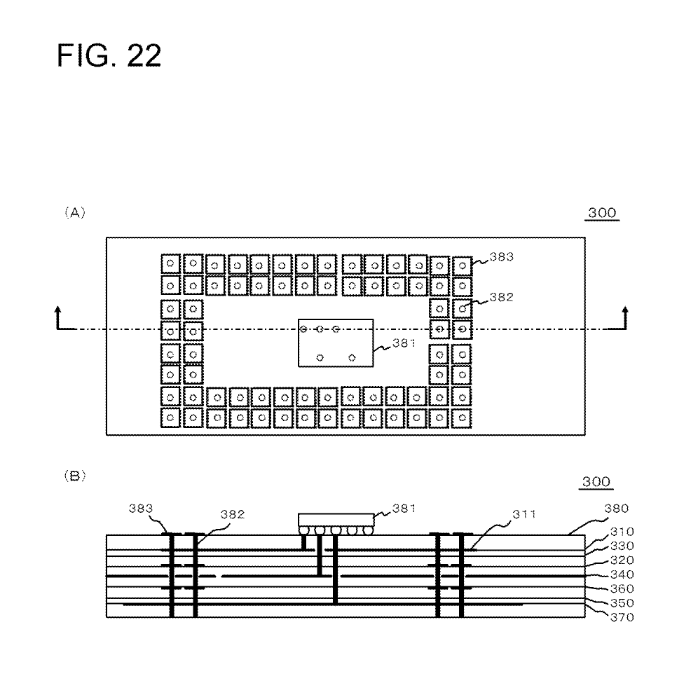

FIG. 22 shows a plan view and a cross-sectional view of a circuit board 300 according to a third embodiment of the invention. More specifically, FIG. 22(A) is a plan view of the circuit board 300 and FIG. 22(B) is a cross-sectional view of the circuit board 300 taken along the indicated sectional line in FIG. 22(A). The circuit board 300 is a multi-layered board including at least an A layer 310, a B layer 320, a C layer 330, a D layer 340, an E layer 350, an F layer 360, a G layer 370, and an H layer 380 which are opposing each other. The circuit board 300 may include a layer other than the eight layers. The circuit board 300 may further include holes or vias not shown in the drawing without conflicting with the configuration of the invention. Signal lines may be arranged in the eight layers without conflicting with the configuration of the invention.

Plural penetration vias 382 are repeatedly arranged in the circuit board 300. The penetration via 382 is formed by forming a conductor on the inner surface of a through-hole penetrating the circuit board 300 from the uppermost surface to the lowermost surface.

The A layer 310 to the G layer 370 are the same as the A layer 110 to the G layer 170 in the circuit board 100 employing the example where the penetration via is used as the connection member and the penetration via is connected to the ground planes 111 and 171, specifically, any example described with reference to FIGS. 6(G), 7(G), 8(F), 9(D), and 13(B), among the examples described in the first embodiment. Here, in this embodiment, the C layer 330 in which a signal line is arranged is located between the A layer 310 in which a ground plane is located and the B layer 320 in which conductor elements are located. The E layer 350 in which a signal line is arranged is located between the F layer 360 in which conductor elements are located and the G layer 370 in which a ground plane is located.

The H layer 380 is a dielectric layer stacked on the ground plane 311 and is exposed from the surface of the circuit board 300. The H layer 380 includes a mounting region on which an electronic device 381 is mounted and conductor elements 383 repeatedly arranged to surround the electronic device 381. The conductor elements 383 are connected to the penetration vias 382 and are exposed from the surface of the circuit board 300.

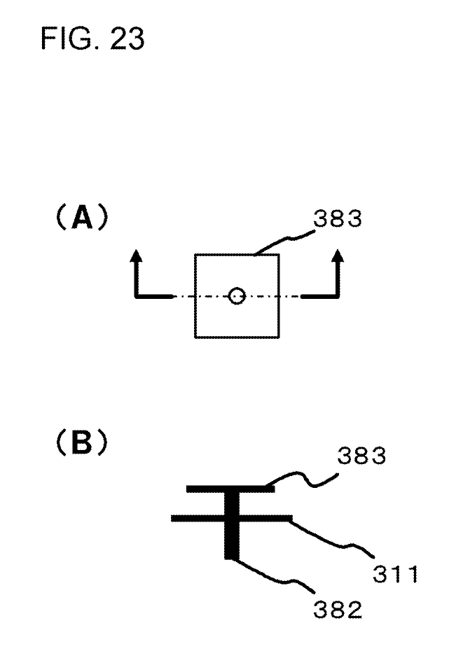

The conductor elements 383 may have various shapes as long as they can constitute an EBG structure. FIGS. 23 to 27 are diagrams illustrating the shapes of a conductor element 383.

FIG. 23(A) is a plan view illustrating an example of the conductor element 383. The conductor element 383 shown in the drawing has a square shape and is connected to the penetration via 382. FIG. 23(B) is a cross-sectional view of the periphery of the conductor element 383 taken along the sectional line marked in FIG. 23(A). The conductor element 383 is opposing the ground plane 311.

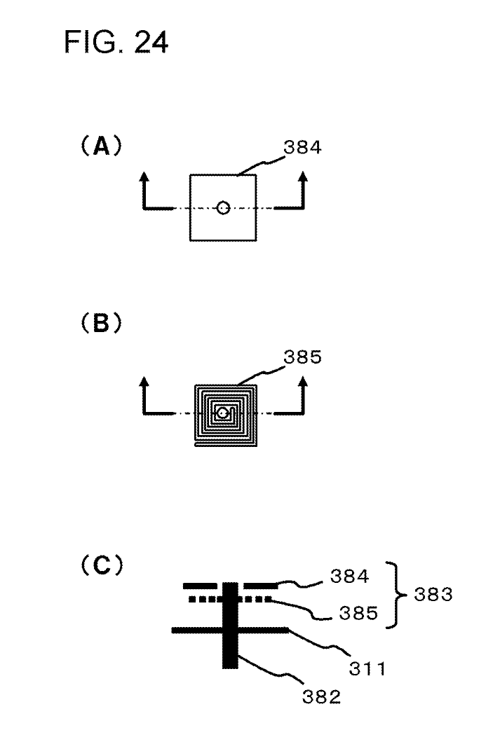

The conductor element 383 to be described with reference to FIG. 24 includes a conductor element 384 formed at the top stage and a conductor element 385 formed below the conductor element 384. FIG. 24(A) is a plan view of the conductor element 384. The conductor element 384 shown in the drawing has a square shape and is not connected to the penetration via 382. FIG. 24(B) is a plan view of the conductor element 385. The conductor element 385 shown in the drawing is a spiral transmission line formed in a planar direction, of which an end is connected to the penetration via 382 and the other end is an open end. FIG. 24(C) is a plan view of the periphery of the conductor element 383 (the conductor element 384 and the conductor element 385) taken along the sectional line marked in FIGS. 24(A) and 24(B). The conductor element 384, the conductor element 385, and the ground plane 311 are opposing each other.

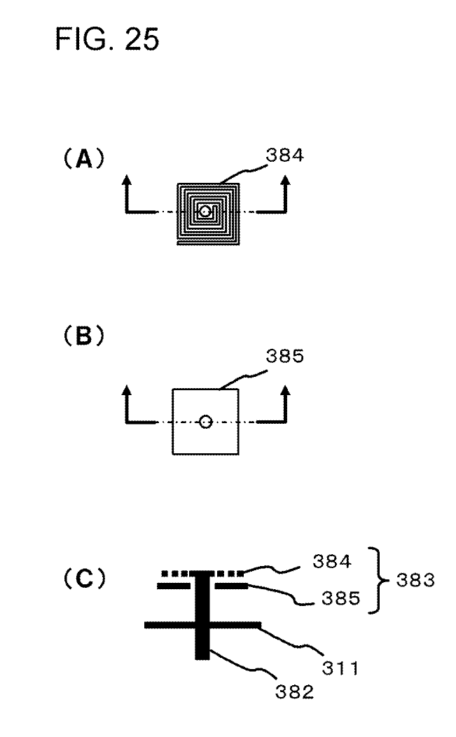

The conductor element 383 to be described with reference to FIG. 25 includes a conductor element 384 and a conductor element 385. FIG. 25(A) is a plan view of the conductor element 384. The conductor element 384 shown in the drawing is a spiral transmission line formed in a planar direction, of which an end is connected to the penetration via 382 and the other end is an open end. FIG. 25(B) is a plan view of the conductor element 385. The conductor element 385 shown in the drawing has a square shape and is not connected to the penetration via 382. FIG. 25(C) is a plan view of the periphery of the conductor element 383 (the conductor element 384 and the conductor element 385) taken along the sectional line marked in FIGS. 25(A) and 25(B). The conductor element 384, the conductor element 385, and the ground plane 311 are opposing each other.

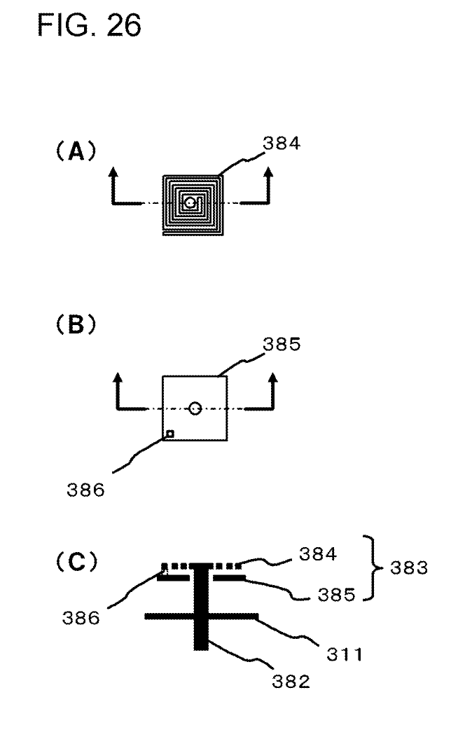

The conductor element 383 to be described with reference to FIG. 26 includes a conductor element 384 and a conductor element 385. FIG. 26(A) is a plan view of the conductor element 384. The conductor element 384 shown in the drawing is a spiral transmission line formed in a planar direction, of which an end is connected to the penetration via 382 and the other end is connected to the conductor element 385 through the connection member 386. FIG. 26(B) is a plan view of the conductor element 385. The conductor element 385 shown in the drawing has a square shape, is connected to the conductor element 384, and is connected to the penetration via 382 through the conductor element 384. That is, the penetration via 382 and the conductor element 385 are not directly connected to each other. FIG. 26(C) is a plan view of the periphery of the conductor element 383 (the conductor element 384 and the conductor element 385) taken along the sectional line marked in FIGS. 26(A) and 26(B). The conductor element 384, the conductor element 385, and the ground plane 311 are opposing each other.

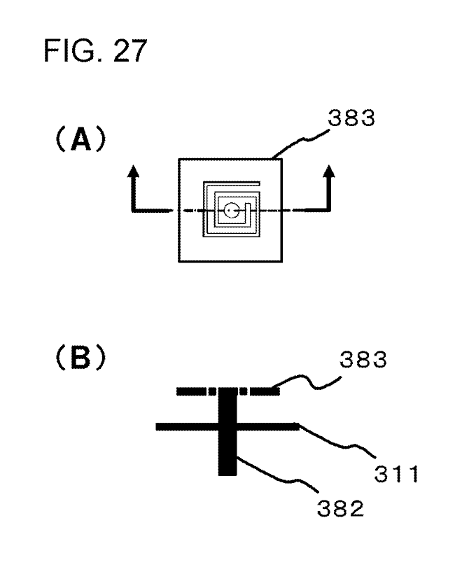

FIG. 27(A) is a plan view illustrating an example of the conductor element 383. The conductor element 383 shown in the drawing is a square conductor and has an opening. An inductor of which an end is connected to the edge of the opening and the other end is connected to the penetration via 382 is formed in the opening. The shape of the inductor is shown to be spiral, but the shape is not limited to this. For example, the inductor may have a polygonal line shape and may have a meandering shape. FIG. 27(B) is a cross-sectional view of the periphery of the conductor element 383 taken along the sectional line marked in FIG. 27(A). The conductor element 383 is opposing the ground plane 311.

The conductor element 383 may have the shape shown in FIG. 4 of Patent Document 2, in addition to the shapes shown in FIGS. 23 to 27.

The advantageous effects of the third embodiment will be described below. The propagation of surface waves propagating from the electronic device 381 to the H layer 380 can be suppressed with the region in which the conductor elements 383 are arranged. Similarly to the first embodiment, it is possible to prevent leakage of noise propagating in the A layer 310 to the G layer 370. In this embodiment, it is possible to constitute an EBG structure even in the surface layer by using the penetration vias formed to constitute the EBG structure in the inner layers in the first and second embodiments. Accordingly, it is possible to effectively utilize the area of the penetration vias in the H layer 380 without wasting the area.

The surface waves means electromagnetic waves propagating because the structure itself in which a dielectric is stacked on a conductive plane serves as a waveguide. It is described above that an EBG structure is constituted on the surface layer using the penetration vias of the circuit board 100, but an EBG structure may be completely similarly constituted on the surface layer by using the penetration vias in the circuit board 200 described in the second embodiment.

### Fourth Embodiment

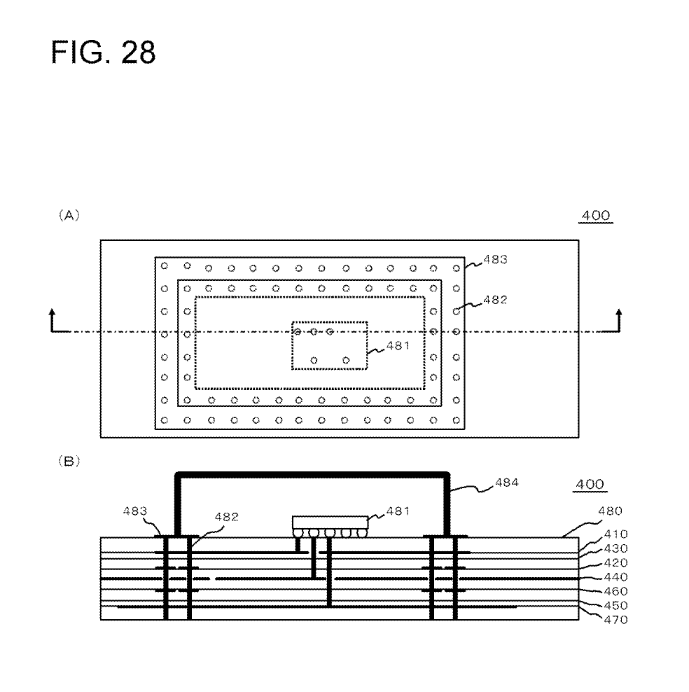

FIG. 28 shows a plan view and a cross-sectional view of a circuit board 400 according to a fourth embodiment of the invention. More specifically, FIG. 28(A) is a plan view of the circuit board 400 and FIG. 28(B) is a cross-sectional view of the circuit board 400 taken along the indicated sectional line in FIG. 28(A). The circuit board 400 is a multi-layered board including at least an A layer 410, a B layer 420, a C layer 430, a D layer 440, an E layer 450, an F layer 460, a G layer 470, and an H layer 480 which are opposing each other. The circuit board 400 may include a layer other than the eight layers. The circuit board 400 may further include holes or vias not shown in the drawing without conflicting with the configuration of the invention. Signal lines may be arranged in the eight layers without conflicting with the configuration of the invention.

Plural penetration vias 482 are repeatedly arranged in the circuit board 400. The penetration via 482 is formed by forming a conductor on the inner surface of a through-hole penetrating the circuit board 400 from the uppermost surface to the lowermost surface.

The A layer 410 to the G layer 470 are the same as the A layer 110 to the G layer 170 in the circuit board 100 employing the example where the penetration via is used as the connection member and the penetration via is connected to the ground planes 111 and 171, specifically, any example described with reference to FIGS. 6(G), 7(G), 8(F), 9(D), and 13(B), among the examples described in the first embodiment. Here, in this embodiment, the C layer 430 in which a signal line is arranged is located between the A layer 410 in which a ground plane is located and the B layer 420 in which conductor elements are located. The E layer 450 in which a signal line is arranged is located between the F layer 460 in which conductor elements are located and the G layer 470 in which a ground plane is located.

The H layer 480 is a dielectric layer stacked on the ground plane 411 and is exposed from the surface of the circuit board 400. The H layer 480 includes a mounting region on which an electronic device 481 is mounted and a metal cap pad 483 surrounding the electronic device 481. The metal cap pad 483 is connected to the penetration vias 482. A metal cap 484 is connected to the metal cap pad 483 so as to cover the electronic device 481.

In this embodiment, it is stated that the circuit board 400 includes a mounting region which is located in the H layer 480 which is the uppermost surface layer and on which the electronic device 481 is mounted and the metal cap 484 which is located in the H layer 480 and which covers the electronic device 481. However, the circuit board 400 may include the mounting region in the lowermost surface layer and may include the metal cap 484 thereon.

Here, the expression, “to cover the electronic device 481”, means to cover the electronic device 481 from all the directions. However, a single pore or plural pores having a diameter sufficiently smaller than the wavelength of noise of a frequency band to be suppressed may be formed in the metal cap 484.

The advantageous effects of the fourth embodiment will be described below. Since the circuit board 400 according to this embodiment includes the metal cap 484, it is possible to block noise generated from the electronic device 481 and propagating in air.

Since the metal cap pad 483 is connected to the penetration vias 482, it is also possible to block noise (surface wave) propagating in the H layer 480. Similarly to the first embodiment, it is possible to prevent the leakage of noise propagating in the A layer 410 to the G layer 470.

Since the metal cap pad 483 is formed in the region on the H layer 400 having the penetration vias 482 and the metal cap 484 is mounted thereon, it is possible to save the space. It is described above that an EBG structure is constituted on the surface layer using the penetration vias of the circuit board 100, but a metal cap may be completely similarly constituted on the surface layer by using the penetration vias in the circuit board 200 described in the second embodiment.

While the embodiment of the invention has been described with reference to the accompanying drawings, the embodiment is only an example of the invention, and various configurations not described above may be employed.

For example, in the second to fourth embodiments, the electronic device is mounted on the surface of the circuit board. However, the circuit board according to the invention may have a mounting region on which the electronic device is mounted in an interlayer between the layers (the second layer and the third layer) in which the ground planes (the third conductor and the fourth conductor) are formed. In this case, since the circuit board is manufactured through a build-up process, it is preferable that the connection members are non-penetrating laser vias.

In the above-mentioned embodiments, the power supply planes (the first conductors) are physically completely separated, but are not limited to this configuration. That is, the circuit board according to the invention may include a joining portion physically jointing one power supply plane to another power supply plane. Here, the jointing portion has only to be an insulator.

The above-mentioned embodiments and the modified examples thereof can be combined without conflicting with each other in details.

Priority is claimed on Japanese Patent Application No. 2010-051079, filed Mar. 8, 2010, the content of which is incorporated herein by reference.

1. A circuit board comprising:
a plurality of first conductors that are arranged with gaps in a first layer;
a first connection member that electrically connects at least one of the plurality of first conductors to an electronic device;
a plurality of second conductors that are repeatedly arranged to surround a first region including at least some of the gaps and at least some of connection points between the first connection member and the first conductors and that are opposing the first conductors;
a third conductor that is located in a second layer and that extends in a second region including the first region and a region opposing the second conductors; and
a fourth conductor that is located in a third layer opposing the second layer with the first layer interposed therebetween and that extends in a third region including the first region and a region opposing the second conductor.

2. The circuit board according to claim 1, wherein a plurality of the first connection members are provided and at least some of the first connection members are connected to the other first conductors, and
wherein the first region includes the connection points present in the other first conductors.

3. The circuit board according to claim 1, further comprising a second connection member connected to the second conductors,
Wherein the second connection member is further connected to the first conductors or is connected to at least one of the third conductor and the fourth conductor.

4. The circuit board according to claim 3, wherein the second conductors are arranged in at least one of an interlayer between the first layer and the second layer and an interlayer between the first layer and the third layer.

5. The circuit board according to claim 4, wherein the second connection member is connected to the third conductor and the fourth conductor and passes through openings formed in the first conductors,
wherein the second conductors are opposing the first conductors and are electrically connected to the second connection member passing through the openings formed in the opposing first conductors, and
wherein the number of layers in which the second conductors are formed is equal to the number of the first layers.

6. The circuit board according to claim 4, wherein a region of the third conductor or the fourth conductor opposing the second conductors is imperforate.

7. The circuit board according to claim 3, wherein the second conductors are arranged at one or both of a position which is opposing the first layer with the second layer interposed therebetween and a position which is opposing the first layer with the third layer interposed therebetween.

8. The circuit board according to claim 7, wherein the second connection member is connected to the first conductors and passes through an opening formed in the third conductor or the fourth conductor, and
wherein the second conductors are opposing the third conductor or the fourth conductor and are electrically connected to the second connection member passing through the opening formed in the opposing third conductor or the opposing fourth conductor.

9. The circuit board according to claim 1, wherein the second conductors are arranged in at least one of the second layer and the third layer.

10. The circuit board according to claim 9, wherein the second conductors are island-like conductors formed in openings of the third conductor or the fourth conductor and the second conductors are connected to the third conductor or the fourth conductor through an inductor.

11. The circuit board according to claim 9, wherein the respective second conductors are a transmission line that is located in an opening of the third conductor or the fourth conductor, of which an end is electrically connected to the edge of the opening and the other end is an open end not connected to the edge of the opening, and
wherein the respective second conductors are opposing the imperforate region of the first conductor.

12. The circuit board according to claim 9, wherein a plurality of the first layers are provided,
wherein the respective second conductors are formed at least one of the plurality of first layers.

13. The circuit board according to claim 1, wherein the first conductors are power supply planes and the third conductor and the fourth conductor are ground planes, and
wherein different potentials are applied to one first conductor and another first conductor of the plurality of first conductors.

14. The circuit board according to claim 1, wherein a signal line is further arranged in the layer in which the second conductors are arranged.

15. The circuit board according to claim 1, wherein an interlayer between the second layer and the third layer includes a mounting region on which the electronic device is mounted.

16. The circuit board according to claim 1, further comprising:
a mounting region that is located in a surface layer and on which the electronic device is mounted; and
a metal cap that is located in the surface layer and that covers the mounting region.

17. The circuit board according to claim 1, wherein the first conductors, the second conductors, the third conductor, and the fourth conductor constitute at least a part of an electromagnetic bandgap structure, and
wherein the electromagnetic bandgap structure has a bandgap range including the frequency of the noise generated from the electronic device.

18. An electronic apparatus comprising:
a plurality of first conductors that are arranged with gaps in a first layer;
an electronic device that is electrically connected to at least one of the plurality of first conductors;
a plurality of second conductors that are repeatedly arranged to surround a first region including at least some of the gaps and at least some of connection points to the electronic device over the first conductors and that are opposing the first conductors;
a third conductor that is located in a second layer and that extends in a second region including the first region and a region opposing the second conductors; and
a fourth conductor that is located in a third layer opposing the second layer with the first layer interposed therebetween and that extends in a third region including the first region and a region opposing the second conductor.

19. A noise blocking method comprising:
when noise generated from an electronic device propagates in at least one of a space between any of a plurality of first conductors arranged with gaps in a first layer and a third conductor extending in a second layer and a space between any of the plurality of first conductors and a fourth conductor extending in a third layer opposing the second layer with the first layer interposed therebetween and is radiated from the gaps to the outside,
blocking the radiated noise by the use of the third conductor and the fourth conductor; and blocking the noise in a space in which any of a plurality of second conductors repeatedly arranged to surround a first region including at least some of the gaps and at least some of connection points to the electronic device of the first conductors and opposing the first conductors is opposing the third conductor or the fourth conductor.

20. The circuit board according to claim 2, further comprising a second connection member connected to the second conductors,
Wherein the second connection member is further connected to the first conductors or is connected to at least one of the third conductor and the fourth conductor.
